(19) United States
(12) Patent Application Publication
(10) Pub. No.: US 2025/0157785 A1
(43) Pub. Date: May 15, 2025

(54) CHARGED PARTICLE BEAM DEVICE ADJUSTMENT METHOD AND CHARGED PARTICLE BEAM DEVICE

(71) Applicant: Hitachi High-Tech Corporation, Tokyo (JP)

(72) Inventors: Hidenori MACHIYA, Tokyo (JP); Yoshifumi SEKIGUCHI, Tokyo (JP); Naoya NAKAI, Tokyo (JP)

(21) Appl. No.: 18/839,987

(22) PCT Filed: Feb. 3, 2023
(86) PCT No.: PCT/JP2023/003515

§ 371 Date: Aug. 20, 2024

(30) Foreign Application Priority Data
Mar. 28, 2022 (WO) PCT/JP2022/014901

(51) Int. Cl. H01J 37/20; H01J 37/22; H01J 37/244; H01J 37/26; H01J 37/28

(52) U.S. Cl. CPC H01J 37/20; H01J 37/222; H01J 37/226; H01J 37/244; H01J 37/265; H01J 37/28; H01J 2237/20292; H01J 2237/24578

(57) ABSTRACT

A light irradiation positioning adjustment method adjusts an irradiation position of first light in a charged particle beam device that irradiates a sample. A particle beam detector detects the particle beam from the sample and generates a signal. A photodetector detects second light emitted from the sample due to the irradiation using the first light and generates a photoelectric signal. An adjustment sample placed on a sample stage with a reference structure is irradiated with the first light and the second light generated by the first light being modulated by the reference structure is detected to generate a photoelectric signal. A command is issued to change the irradiation position of the first light so as to pass through the reference structure based on a change in the photoelectric signal such that an irradiation position of the charged particle beam and the irradiation position of the first light match.

### TECHNICAL FIELD

The present disclosure relates to a charged particle beam device adjustment method and a charged particle beam device.

### BACKGROUND ART

It is known that when a sample is observed and analyzed using a charged particle beam, charging of a sample causes variations in a luminance value and distortions of a secondary charged particle beam image. In this regard, there is a technique of controlling charging by irradiating an irradiation region of a charged particle beam with an electromagnetic wave such as light.

PTL 1 discloses a technique for preventing charging by emitting a light beam as well as a charged particle beam.

PTL 2 discloses a charged particle beam device that determines whether an irradiation position of a primary charged particle beam and a light irradiation position match based on a difference between a first observation image acquired when only the primary charged particle beam is emitted and a second observation image acquired when light is emitted in addition to the primary charged particle beam. In addition, PTL 2 discloses that an adjustment sample used to specify the light irradiation position has a pattern repeatedly arranged in a grid shape when viewed from an upper surface, and pattern position coordinates can be recognized by marks, and the irradiation position of the primary charged particle beam is matched with the light irradiation position by adjusting the difference to be small.

PTL 3 discloses an irradiation position adjustment method for a charged particle beam and a light beam.

PTL 4 discloses a method for displaying an ultraviolet ray irradiation region as a photoelectron image and displaying the photoelectron image and a reflected electron image on a monitor while being superimposed on each other.

PTL 5 discloses a method for optically detecting a height in which two-dimensional slit light is projected onto an object from diagonally above, reflection light is detected, and a slit part having a large detection error is eliminated to detect a height of the object.

### CITATION LIST

### Patent Literature

PTL 1: JP2003-151483A
PTL 2: WO2020/115876
PTL 3: US2018/0166247
PTL 4: JP2009-004114A
PTL 5: JP2007-132836A

### SUMMARY OF INVENTION

### Technical Problem

In a device that emits light and a charged particle beam, it is necessary to adjust a relative light irradiation position with respect to an irradiation position of a charged particle beam. For example, when charging of a sample is eliminated by light irradiation, it is necessary to accurately match the irradiation region of the charged particle beam where the charging occurs and the light irradiation region.

An object of the present disclosure is to accurately match an irradiation position of a charged particle beam and a light irradiation position by a simple method.

### Solution to Problem

A light irradiation position adjustment method according to an aspect of the present disclosure is a method for adjusting an irradiation position of first light in a charged particle beam device, the charged particle beam device including: a particle beam source configured to irradiate a sample with a charged particle beam; a particle beam detector configured to detect a particle beam from the sample and generate a particle beam electric signal; a light source configured to generate the first light with which the sample is irradiated; a movable mechanism configured to move the irradiation position of the first light; a photodetector configured to detect second light emitted from the sample due to the irradiation using the first light and generate a photoelectric signal; a sample stage having a configuration allowing the sample to be placed and moved thereon; and a control device, the method including: the light source irradiating, with the first light, an adjustment sample placed on the sample stage and including a reference structure; the photodetector detecting the second light, that is generated by the first light being modulated by the reference structure, and sending the photoelectric signal to the control device; and the control device issuing a command to change the irradiation position of the first light so as to pass through the reference structure, and performing an adjustment, based on a change in the photoelectric signal, the movable mechanism such that an irradiation position of the charged particle beam and the irradiation position of the first light match.

A charged particle beam device according to another aspect of the present disclosure includes: a particle beam source configured to irradiate a sample with a charged particle beam; a particle beam detector configured to detect a particle beam from the sample and generate a particle beam electric signal; a light source configured to generate first light with which the sample is irradiated; a movable mechanism configured to move an irradiation position of the first light; a photodetector configured to detect second light emitted from the sample due to the irradiation using the first light and generate a photoelectric signal; a sample stage having a configuration allowing the sample to be placed and moved thereon; and a control device, in which the light source irradiates, with the first light, an adjustment sample placed on the sample stage and including a reference structure, the photodetector detects the second light generated by modulation of the first light by the reference structure and sends the photoelectric signal to the control device, and the control device issues a command to change the irradiation position of the first light so as to pass through the reference structure, and performs an adjustment, based on a change in the photoelectric signal, the movable mechanism such that an irradiation position of the charged particle beam and the irradiation position of the first light match.

### Advantageous Effects of Invention

According to the present disclosure, the irradiation position of the charged particle beam and the light irradiation position can be accurately matched by a simple method.

### BRIEF DESCRIPTION OF DRAWINGS

FIG. 1 is a schematic configuration diagram showing a charged particle beam device according to Embodiment 1.

FIG. 2 is a diagram showing 10 light irradiation region on a sample.

FIG. 3A is a cross-sectional view showing an example of an adjustment sample 6 in FIG. 1.

FIG. 3B is a top view showing the adjustment sample 6 in FIG. 3A.

FIG. 3C is an enlarged view of a region 6p indicated by a dotted square in FIG. 3B.

FIG. 3D is a cross-sectional view showing a modification of the adjustment sample 6 in FIG. 3A.

FIG. 4 is a top view showing an overall structure of the adjustment sample used in Embodiment 1.

FIG. 5 is a configuration diagram showing an example of a control system 5 in FIG. 1.

FIG. 6 is a flowchart showing a light irradiation position adjustment method according to Embodiment 1.

FIG. 7A is a diagram showing an adjustment GUI according to Embodiment 1.

FIG. 7B is a diagram showing the adjustment GUI according to Embodiment 1.

FIG. 8A is a graph showing an example of mirror angle dependence of secondary light intensity Embodiment 1.

FIG. 8B is a graph showing another example of the mirror angle dependence of the secondary light intensity in Embodiment 1.

FIG. 9A is a cross-sectional view showing an example of a reference structure used in Modification 1.

FIG. 9B is a cross-sectional view showing another example of the reference structure used in Modification 1.

FIG. 9C is a cross-sectional view showing another example of the reference structure used in Modification 1.

FIG. 10 is a cross-sectional view showing an example of a reference structure used in Modification 2.

FIG. 11A is a cross-sectional view showing an example of a reference structure used in Modification 3.

FIG. 11B is a cross-sectional view showing another example of the reference structure used in Modification 3.

FIG. 12 is a schematic diagram showing an influence when a height of a sample changes in Embodiment 2.

FIG. 13 is a schematic configuration diagram showing a charged particle beam device according to Embodiment 2.

FIG. 14A is a cross-sectional view showing an example of an adjustment sample used in Embodiment 2.

FIG. 14B is a cross-sectional view showing another example of the adjustment sample used in Embodiment 2.

FIG. 15 is a flowchart showing a mirror angle calibration method according to Embodiment 2.

FIG. 16A is a diagram showing an example of a setting screen of a calibration GUI according to Embodiment 2.

FIG. 16B is a diagram showing an example of a measurement value and an adjustment result of a height of the sample in the calibration GUI according to Embodiment 2.

FIG. 17 is a flowchart showing an irradiation position adjustment method according to Embodiment 2.

FIG. 18 is a graph for illustrating a mirror angle determination method in Embodiment 2.

FIG. 19 is a configuration diagram showing a light irradiation system and a light detection system according to Embodiment 3.

FIG. 20A is a configuration diagram showing a light irradiation system and a light detection system according to Embodiment 4.

FIG. 20B is a configuration diagram showing a modification of an optical system.

FIG. 20C is a configuration diagram showing a modification of the optical system.

FIG. 21A is a graph showing signal intensity X1 detected by a light receiving element 2b in FIG. 20A.

FIG. 21B is a graph showing signal intensity X2 detected by a light receiving element 2c in FIG. 20A.

FIG. 21C is a graph showing an electric signal X3 calculated by a signal processing unit 2d in FIG. 20A.

FIG. 22 is a top view showing an example of an adjustment sample according to Embodiment 5.

FIG. 23 is a flowchart showing an adjustment procedure for obtaining a coordinate conversion expression according to Embodiment 5.

FIG. 24 is a diagram showing an example of a display GUI of an adjustment result according to Embodiment 5.

FIG. 25 is a top view showing a relationship between an adjustment sample and a light irradiation position used in Embodiment 6.

FIG. 26 is a graph showing signal intensity obtained in Embodiment 6.

FIG. 27A is a diagram for illustrating a problem when a boundary line and movable axes obliquely intersect with each other in Embodiment 6.

FIG. 27B is a diagram showing a case where the boundary line and the movable axis intersect at a right angle in Embodiment 6.

FIG. 28 is a flowchart showing a light irradiation position adjustment method according to Embodiment 6.

FIG. 29 is a diagram showing an adjustment GUI according to Embodiment 6.

FIG. 30 is a diagram showing a second adjustment axis adjustment method in Embodiment 6.

FIG. 31 is a diagram showing an adjustment GUI according to Embodiment 6.

FIG. 32A is a diagram illustrating a secondary light amount before a light irradiation position is moved in Embodiment 6.

FIG. 32B is a diagram illustrating the secondary light amount when the light irradiation position is moved from a position in FIG. 32A.

FIG. 32C is a diagram illustrating a change rate of the secondary light amount between FIG. 32A and FIG. 32B.

FIG. 33 is a graph showing the change rate of the secondary light amount.

FIG. 34A is a top view showing an example of a reference structure having boundary lines in two directions on an adjustment sample.

FIG. 34B is a top view showing another example of the reference structure having the boundary lines in two directions on the adjustment sample.

FIG. 35 is a top view showing a modification of the adjustment sample that can be used in Embodiment 6.

FIG. 36A is a graph showing an electric signal emitted from a reference structure 6a in FIG. 35 and detected by the light receiving element 2b.

FIG. 36B is a graph showing an electric signal emitted from a reference structure 6m in FIG. 35 and detected by the light receiving element 2c.

FIG. 36C is a graph showing an electric signal calculated by the signal processing unit 2d.

### DESCRIPTION OF EMBODIMENTS

A light irradiation position adjustment method in a charged particle beam device according to the present disclosure uses an adjustment sample including a reference structure that generates new light according to irradiation of light, a control device that controls a light irradiation position, and a photodetector that detects the light and generates an electric signal, and the control device moves the light irradiation position so as to pass through the reference structure, and adjusts a relative light irradiation position with respect to an irradiation position of a charged particle beam based on a change in the electric signal.

Hereinafter, embodiments of the present disclosure will be described with reference to the drawings. The content of the present disclosure is not limited to the embodiments described later, and various modifications are possible within the scope of the technical concept thereof. In addition, parts corresponding to those in the drawings used in the description of the embodiments described later are denoted by the same reference numerals, and redundant description is omitted.

### Embodiment 1

In the present embodiment, a case where charging generated in a sample by irradiation of a charged particle beam is eliminated by an electric charge generated by light irradiation will be described as an example. In this example, since the electric charge generated by the light is delivered to a charged region on the sample, an adjustment method for accurately matching a light irradiation position and an electron-beam irradiation position is necessary. However, an effect of the light irradiation is not limited to only charging elimination. In addition, for example, measurement of an absorption spectrum or an emission spectrum, shape observation using a microscope, and the like are also targets, and the adjustment method described in the present embodiment can be used to match an irradiation range of the charged particle beam and a light observation range.

FIG. 1 is a schematic configuration diagram showing a charged particle beam device according to the present embodiment.

The charged particle beam device includes a light irradiation system 1, a light detection system 2, an electron optical system 3, a sample stage system 4 (sample stage), and a control system 5 (control device). By using an adjustment sample 6, a relative light irradiation position with respect to an electron irradiation position is adjusted.

The electron optical system 3 is configured to generate an SEM image, and includes an electron-beam source 3a (particle beam source), an electron-beam collection unit 3b, an electron-beam detection unit 3c (particle beam detector), and an SEM image generation unit 3d. An electron beam emitted from the electron-beam source 3a passes through the electron-beam collection unit 3b and is emitted to one point on a sample placed on a sample table. A signal electron emitted from the sample is converted into an electric signal (particle beam electric signal) by the electron-beam detection unit 3c. The SEM image generation unit 3d generates an image by recording the generated electric signal. Here, the SEM is an abbreviation of a scanning electron microscope.

The sample stage system 4 includes a sample table 4a on which a sample is placed and movable stages 4b that move the sample table 4a. The sample is placed on the sample table 4a, and a position thereof can be changed by the movable stages 4b. In this drawing, an adjustment sample 6 is placed on the sample table 4a. The adjustment sample 6 has a reference structure 6a.

The light irradiation system 1 includes a light source 1a and a light irradiation position adjustment unit 1b. The light irradiation position adjustment unit 1b includes an optical element 1c and a movable stage 1d. The light source 1a is any light source having a wavelength ranging from X-rays to infrared rays, and may be a laser light source, an LED, a lamp, or the like. The wavelength may be fixed, or a wavelength-tunable light source may be used. The light source 1a may be a multicolor light source in which a plurality of light sources are combined. Furthermore, the light source 1a may be a pulse light source or a continuous wave light source. For example, when the light source 1a is used for a purpose of further eliminating charging of the sample by light, since it is necessary to excite an electric charge in the sample, it is desirable that the light source 1a emits high-energy light, particularly wavelength continuous light having a wavelength of 450 nm or less.

The light source 1a emits a light beam Ray1 toward the light irradiation position adjustment unit 1b. The optical element 1c of the light irradiation position adjustment unit 1b is a mirror. The movable stage 1d adjusts an angle of the optical element 1c, so that the light beam Ray1 is emitted to an appropriate position on the sample. Here, the light irradiation position adjustment unit 1b is a movable mechanism capable of moving an irradiation position of the light beam Ray1. Hereinafter, the position irradiated with the light beam Ray1 is also referred to as a “light irradiation position”.

As the optical element 1c, a lens or a prism can also be used. In this case, the light irradiation position may be changed by moving a position of the optical element 1c by the movable stage 1d.

In this drawing, the light beam Ray1 is obliquely incident through the light irradiation position adjustment unit 1b and emitted on the sample so as not to affect a trajectory of the electron beam. The light beam Ray1 may be emitted as parallel light as it is, or may be collected and emitted by using a lens or a curved mirror. However, an incidence method is not limited to this method, and for example, a mirror having a hole through which an electron beam passes may be provided in the electron optical system 3, the light beam Ray1 may be incident in parallel to the electron beam, and the sample may be irradiated with the light beam Ray1 perpendicularly. Alternatively, the light may be guided to the charged particle beam device through an optical fiber or the like. In any method, it is sufficient to irradiate the sample with the light beam Ray1.

When the light beam Ray1 is incident on the reference structure 6a, secondary light Ray2, which is light obtained by modulation of the light beam Ray1, is generated. Here, the light obtained by modulation is, for example, new light generated according to the light beam Ray1. Examples of the secondary light Ray2 include diffracted light, fluorescence, and scattered light. Alternatively, when a micromirror that selectively reflects light only in a specific direction from the reference structure 6a to a detector (photodetector) provided in the light detection system 2 is used, the reflected light can be considered as light newly generated from the reference structure 6a. Therefore, in this case, it may be considered that the reflected light (reflection light) is also included in the secondary light.

However, the light obtained by modulation is not limited to the secondary light shown in the above example. For example, since the light attenuated by the reference structure 6a absorbing the light is not the new light emitted by the reference structure 6a, it can be considered that the light obtained by modulation is not the secondary light but is a kind of light modulated by the reference structure 6a. Therefore, such attenuated light can also be used to adjust the light irradiation position.

In the present specification, the light emitted from the light source 1a to the sample is referred to as “first light”. Light traveling from the sample toward the photodetector, such as the secondary light or the attenuated light, is referred to as “second light”.

The adjustment method based on light absorption will be described in detail in a modification of Embodiment 4.

In the following description, a case where the reference structure 6a emits the secondary light will be described.

The light detection system 2 detects the secondary light Ray2. The light detection system 2 includes a light receiving element that converts energy of the secondary light Ray2 into an electric signal (photoelectric signal). Although not described in the present embodiment, an optical filter or a lens may be additionally used to clearly detect the secondary light Ray2. The light receiving element is an element that converts light into an electric signal, and a CMOS, a CCD camera, a photomultiplier tube, a silicon photomultiplier, a photodiode, or the like can be used. Alternatively, as described in the present embodiment, the detection may be performed by the electron-beam detection unit 3c of the electron optical system 3. For example, as the electron-beam detection unit 3c, an Everhart-Thornley detector (hereinafter, referred to as an “ET detector”) is typical. The ET detector includes a scintillator and a light guide in addition to the light receiving element. The secondary light Ray2 is converted into an electric signal by a configuration in which the secondary light Ray2 is directly incident on the light receiving element or a configuration in which fluorescence is emitted by the scintillator and the fluorescence is detected by the light receiving element. Alternatively, the secondary light Ray2 may be incident on the light guide in the middle, guided, and incident on the light receiving element.

As another detector, there is a Si photodiode which is a semi-conductor detector. Since the Si photodiode can detect both light and electrons, the Si photodiode can be used for the light detection system 2. When the electron-beam detection unit 3c is used as in the present embodiment, a circuit or software for processing an electric signal of a detector can be shared, making this suitable for the SEM or an electron-beam lithography device having an SEM function.

According to this configuration, an effect such that the irradiation position can be adjusted without adding a mechanism or software to the existing charged particle beam device is exerted.

A method in which the light source 1a modulates an output at a frequency f and the light detection system 2 extracts and detects only a component of the frequency f, that is, lock-in detection may be performed. By performing the lock-in detection, an effect such that an adjustment method that is robust against disturbances such as light incident from the outside of the charged particle beam device can be exerted.

Next, a light irradiation region and a principle of the adjustment method will be described.

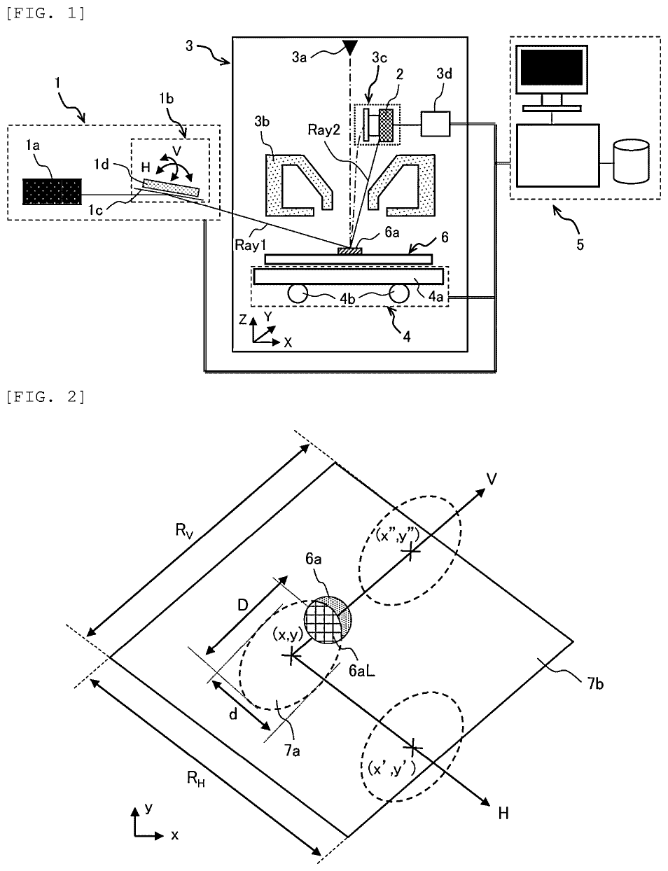

FIG. 2 is a diagram showing a light irradiation region on the sample.

As shown in this drawing, when laser light is obliquely incident on the sample, an elliptical region 7a is irradiated. A minor axis diameter of the elliptical region 7a is set as d, a major axis diameter thereof is set as D, and a center position thereof is set as (x, y). Although details will be described in the latter half of the present embodiment, it is assumed that the reference structure 6a is adjusted by the sample stage system 4 so that a center of the reference structure 6a becomes an electron-beam irradiation position. A part where the elliptical region 7a and the reference structure 6a are overlapped is a region 6al, and the secondary light is emitted from the region 6aL.

In the following description, it is assumed that the elliptical region 7a has a spatial distribution in which a power density at the center is high and the power density decreases as a distance from the center increases. For example, a Gaussian spatial distribution generated when a laser is used as a light source is considered.

A secondary light amount is determined by an area of the region 6aL and the distance from the center of the elliptical region 7a. In particular, in a case where a size of the reference structure 6a is smaller than that of the elliptical region 7a, when the center of the reference structure 6a and the center of the elliptical region 7a match, the secondary light amount is maximum. Therefore, if the light irradiation position (x, y) is adjusted such that the secondary light amount is maximum, the center of the reference structure 6a and the light irradiation position can be matched.

The center of the reference structure 6a is adjusted in advance by the electron optical system 3 and the sample stage system 4 so as to match the electron-beam irradiation position. Therefore, by using the reference structure 6a in accordance with the above principle, the light irradiation position and the electron-beam irradiation position can be accurately matched. In the present embodiment, a case where the irradiation region is an ellipse is shown as an example, but the irradiation region may be a perfect circle, that is, d=D.

The center position (x, y) of the light can be adjusted by a movable unit that moves an angle of the mirror. A movable axis of the movable unit may be in only one direction, but in a case of including movable axes in two directions (H, V), it is more desirable that the irradiation position can be set to any coordinate in an X-Y plane, that is, in a sample plane. For example, when a movable axis H is moved, the irradiation position moves to (x′, y′). Similarly, when a movable axis V is moved, the irradiation position moves to (x″, y″). A range within which the irradiation position can be moved when these movable axes (H, V) are moved to the maximum will hereinafter be referred to as an irradiation position movable range 7b. A size of the irradiation position movable range 7b in the H direction is set as RH, and a size in the V direction is set as Rv.

Next, an example of the adjustment sample 6 will be described.

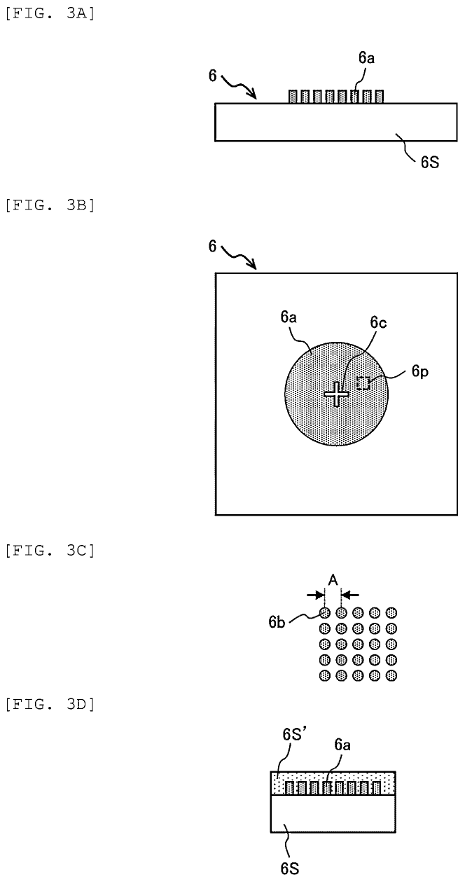

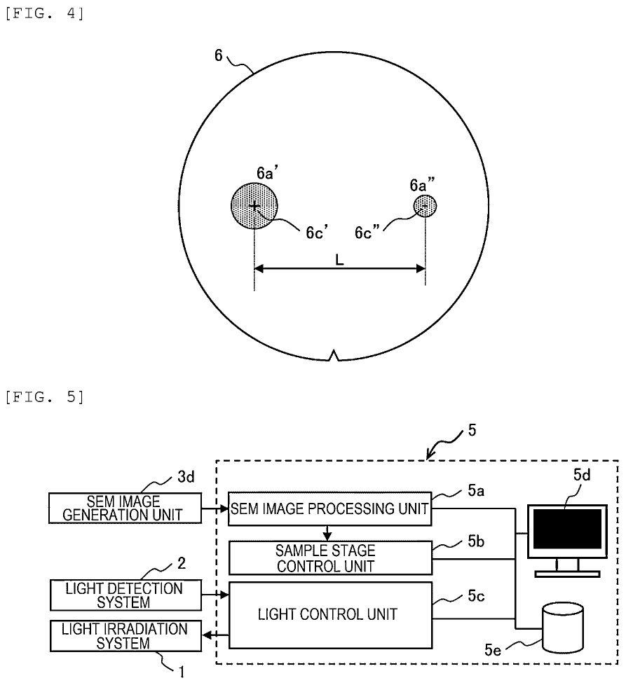

FIG. 3A is a cross-sectional view showing an example of the adjustment sample 6 in FIG. 1.

As shown in FIG. 3A, the adjustment sample 6 includes a flat substrate 6S and the reference structure 6a which is an aggregate of a plurality of fine protrusions provided in a central portion of the substrate 6S. The substrate 6S is formed of, for example, a Si substrate. The reference structure 6a is formed of a plurality of protrusions having a height of, for example, about 100 nm, and a material thereof is, for example, Si. The reference structure 6a emits the secondary light Ray2 according to irradiation of the light beam Ray1.

FIG. 3B is a top view showing the adjustment sample 6 in FIG. 3A.

In FIG. 3B, the reference structure 6a has a circular shape. A cross-shaped center mark 6c is provided at the center of the reference structure 6a.

FIG. 3C is an enlarged view of a region 6p indicated by a dotted square in FIG. 3B.

In FIG. 3C, the region 6p of the reference structure 6a has a structure in which a plurality of protrusions 6b are arranged at equal intervals in vertical and horizontal directions. Each of the protrusions 6b has a columnar shape. A diameter of each of the protrusions 6b is, for example, about 100 nm. A distance between the adjacent two protrusions 6b, that is, a period A satisfies the following relational expression, where a wavelength of light is set as λ, a refractive index of a medium in which the light is incident on the periodic structure is set as n, and the minor axis diameter of the elliptical region 7a (FIG. 2) is set as d.

$$λ / n < A < d$$

According to such a structure, a periodic structure having at least one period is present in the light irradiation region (elliptical region 7a), and the period A of the periodic structure is larger than the wavelength λ, and thus the periodic structure acts as a diffraction grating. If the periodic structure is appropriately designed, diffracted light can be generated in a detector direction, and thus the diffracted light can be used as the secondary light Ray2. Since the diffracted light can be diffracted at a specific diffraction angle, the secondary light Ray2 can be selectively emitted in the detector direction. Therefore, an effect such that the secondary light Ray2 can be reliably detected is exerted.

The refractive index of a medium n is, for example, a refractive index of a vacuum n=1 in a case where the adjustment sample is placed in the vacuum. It is desirable that the periodic structure is made of Si, SiO₂, or the like which is less likely to be deteriorated by irradiation of ultraviolet light or an electron beam or exposure to the atmosphere. This is because an effect of allowing stable use for a long period of time is exerted.

FIG. 3D is a cross-sectional view showing a modification of the adjustment sample 6 in FIG. 3A.

In FIG. 3D, the reference structure 6a of the adjustment sample 6 is covered with a protective layer 6s′. A material of the protective layer 6S′ may be any material through which the light beam Ray1 is transmitted, and for example, can use SiO₂. In this case, the refractive index of a medium n is a refractive index of the protective layer 6S′.

Accordingly, the adjustment sample 6 has the protective layer 6S′, so that the reference structure 6a can be protected from foreign matter. Since the reference structure 6a is not damaged even when the adjustment sample 6 is cleaned by ultrasonic cleaning or the like, an effect such that the adjustment sample 6 can be repeatedly used is exerted.

An outer shape of the reference structure 6a may be any shape, but is more preferably a shape having rotational symmetry with respect to the center of the reference structure 6a. This is because according to such a shape, an amount of the secondary light Ray2 emitted from a portion overlapping the light irradiation region (elliptical region 7a) monotonically increases according to a distance from the center regardless of the direction of the reference structure 6a, and thus the position adjustment is simplified. For example, the outer shape of the reference structure 6a may be a perfect circle as shown in the present embodiment. Alternatively, a shape obtained by an approximation of a perfect circle using a polygon may be used.

The center mark 6c is formed by removing a part of the protrusion 6b forming the reference structure 6a to expose the Si substrate of the lower layer. The reference structure 6a may be formed in such a manner that the protrusion 6b is not formed in a portion to be the center mark 6c.

Alternatively, a protrusion having a shape different from that of the protrusion 6b may be disposed at the position of the center mark 6c. In this case, a material of the protrusion constituting the center mark 6c may be the same as that of the reference structure 6a, or another material such as metal may be used.

The center mark 6c is used when the center of the reference structure 6a is confirmed by the SEM image and the sample stage system 4 is moved. Therefore, the shape of the center mark 6c may be any shape as long as the center can be confirmed by the SEM image, and may be a circular shape, an elliptical shape, an L shape, a rectangular shape, or the like. An outer dimension of the center mark 6c needs to be within a range of 10 nm or more and 1 mm or less, and is a dimension within a field of view of the SEM. It is more desirable that the outer dimension of the center mark 6c is smaller than a light irradiation diameter d. This is because a decrease in the secondary light intensity due to the center mark 6c can be prevented. Alternatively, when a size of the reference structure 6a is such a size that the reference structure 6a enters the SEM image, that is, about several μm, the center mark can be omitted because the center can be confirmed using the reference structure 6a itself as a marker.

FIG. 4 is a top view showing an overall structure of the adjustment sample used in the present embodiment.

The adjustment sample 6 shown in this drawing includes two reference structures, a coarse adjustment reference structure 6a′ and a fine adjustment reference structure 6a″.

Since an outer shape of the coarse adjustment reference structure 6a′ is larger than an outer shape of the fine adjustment reference structure 6a″, it is suitable for coarsely adjusting the light irradiation position. On the other hand, by making an outer dimension of the fine adjustment reference structure 6a″ smaller than the light irradiation diameter d (FIG. 2), an amount of change in the secondary light amount with respect to a deviation of the light irradiation position becomes large, and thus the light irradiation position can be adjusted more accurately. In a case where the adjustment sample is used for regular fine adjustment of the light irradiation position or the like, since it is considered that the deviation of the light irradiation position is small, an adjustment sample from which the coarse adjustment reference structure 6a′ is omitted may be used.

In the present embodiment, both the coarse adjustment reference structure 6a′ and the fine adjustment reference structure 6a″ have the same periodic structure. That is, both have a structure in which the plurality of protrusions 6b are arranged at the same interval. In this way, since the light detection system 2 only needs to respond the secondary light Ray2 of a single type, an effect such that the configuration of the optical system can be simplified, and the adjustment sample 6 is produced easily is exerted.

Alternatively, the coarse adjustment reference structure 6a′ and the fine adjustment reference structure 6a″ may be of different types. For example, in the case of using the periodic structure, the dimension of the reference structure cannot be made smaller than the period A, but by using, for example, a phosphor, a smaller reference structure can be produced, which is suitable for adjustment with high accuracy.

Subsequently, the arrangement of the plurality of coarse adjustment reference structures 6a′ and the fine adjustment reference structures 6a″ will be described.

The coarse adjustment reference structure 6a′ and the fine adjustment reference structure 6a″ need to have a large distance L from the adjacent reference structure such that the secondary light can be distinguished from the secondary light Ray2 emitted from the adjacent reference structure. Specifically, L>R. Here, R represents a larger value of the movable ranges R_{H} and R_{V}. More preferably, L>R+D/2 is satisfied in consideration of the major axis diameter D of the elliptical region 7a (FIG. 2) which is the light irradiation region. Such arrangement provides an effect of accurately adjusting the irradiation position without confusion with a secondary light signal of the adjacent reference structure.

When a reference structure that emits a different type of the secondary light Ray2 is arranged adjacently, the reference structure may be arranged in a distance shorter than the distance L described above. Here, the different type of the secondary light means, for example, secondary light having a different wavelength. The fluorescence is light having a wavelength different from that of the incident light, and thus can be achieved by a combination of a periodic structure that generates diffracted light and a phosphor, or may be achieved by a combination of phosphors that emit light having different wavelengths. By changing the wavelength of the secondary light emitted from the adjacent structure in this way, the secondary light from the adjacent reference structure can be eliminated by a color filter or the like. Alternatively, when the reference structure having the periodic structure is adjacent to the reference structure in which polarization of the secondary light is different from that of the incident light, for example, when the phosphor or a scatterer is provided adjacently, the secondary light signal from the adjacent structure can be separated by using a polarizer.

Sizes of the center mark 6c′ of the coarse adjustment reference structure 6a′ and the center mark 6c″ of the fine adjustment reference structure 6a″ may be enlarged or reduced in accordance with outer shapes of the respective reference structures. However, in the adjustment of the sample stage position using the SEM image, it is preferable to adjust the sample stage position at the same SEM magnification because an adjustment accuracy of the SEM image can be set to the same degree. Therefore, the dimension of the coarse adjustment center mark 6c′ is more preferably the same as the dimension of the fine adjustment center mark 6c″.

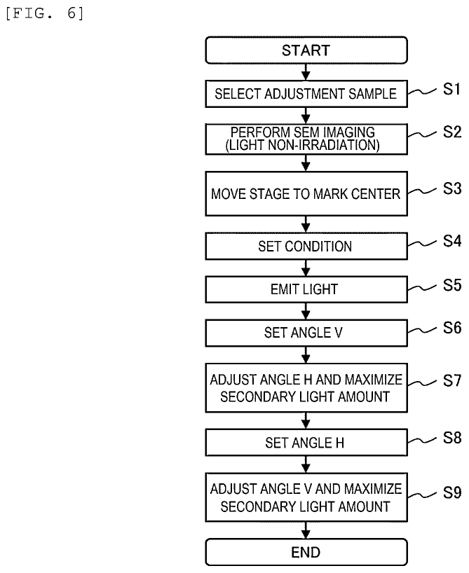

FIG. 5 is a configuration diagram showing an example of the control system 5 in FIG. 1.

The control system 5 includes an SEM image processing unit 5a, a sample stage control unit 5b, a light control unit 5c, a display unit 5d, and a storage unit 5e. The SEM image processing unit 5a detects the center mark 6c of the reference structure 6a of the adjustment sample 6 shown in FIG. 3 based on the SEM image generated by the SEM image generation unit 3d. The sample stage control unit 5b moves the movable stage 4b (FIG. 1) such that the center mark 6c of the reference structure 6a comes to the center of the SEM image. The light control unit 5c controls a mirror angle (H, V) based on signal intensity of the secondary light Ray2 to adjust the light irradiation position. The display unit 5d displays the SEM image and an adjustment result. The storage unit 5e records the adjusted mirror angle.

A basic operation of the light irradiation position adjustment method will be described with reference to FIGS. 6, 7A, 7B, 8A, and 8B.

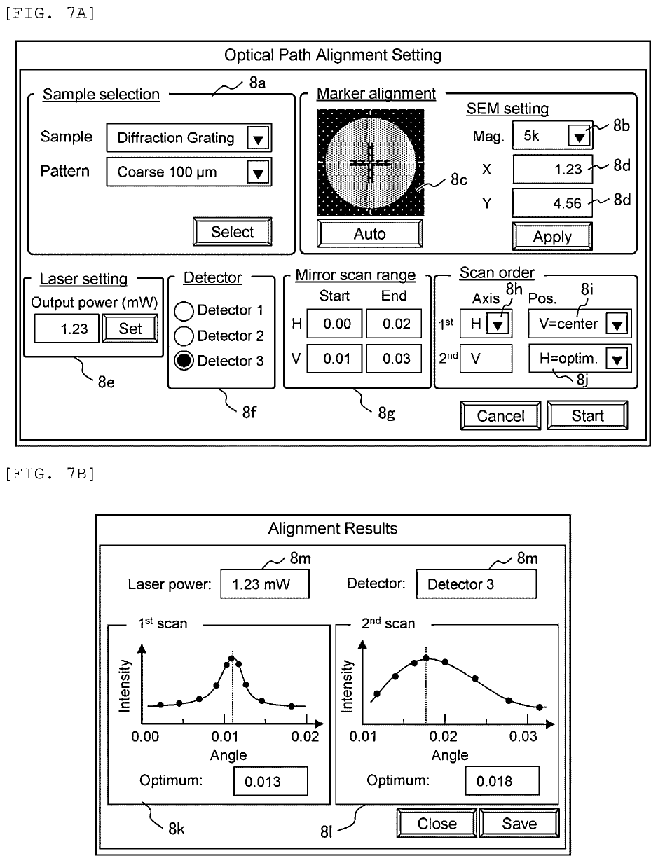

First, a user selects the adjustment sample 6 and the reference structure 6a to be used (step S1). For example, as shown in FIG. 7A, the user can select from a list by using a GUI (8a). The control device places the adjustment sample on the sample table by using a transfer arm or the like according to the selection by the user. Furthermore, the control device moves the sample stage to a position where the selected reference structure appears in the SEM image.

Next, the stage is moved to the mark center while confirming the SEM image (steps S2 to S3). The user selects a magnification at which the center mark can be confirmed by a GUI (8b). The control device automatically moves the sample stage by an algorithm such as pattern matching. Alternatively, the user manually observes an SEM image 8c and sets X and Y coordinates 8d of the sample stage so that the center mark of the reference structure is located at the center of the image. By these procedures (steps S1 to S3), a center of an electron-beam irradiation range matches the center of the reference structure.

Next, the user sets a condition for the light irradiation position adjustment (step S4). First, the user sets an output (setting item 8e) of the laser to be emitted so as to prevent a signal of the detector from being saturated. Subsequently, the detector (setting item 8f) that detects the secondary light Ray2 is selected from the list. For example, in the present embodiment, it is desirable to select the electron-beam detection unit 3c at a position where the secondary light Ray2 is most easily incident. Subsequently, a scan range (setting item 8g) of the mirror angle is set for each of the two axes H and V. The scan range is a range in which the mirror angle is changed to search for an optimal mirror angle, and for example, start and end positions of the scan can be set on the GUI. Alternatively, although shown, a GUI configuration in which a center and a width of a range can be designated may be used.

The user also selects which of the two axes H and V is to be first adjusted by a GUI (8h). In the following description, a case where the axis H is selected to be first adjusted will be described as an example. Conversely, if the axis V is set to be first adjusted, the adjustment can also be performed in the same procedure. In this case, the user can use a GUI (8i) to select a value to which an angle of the unselected axis, that is, the axis V is set. For example, it is possible to specify that a value in the center of the scan range set by the user is used, or to manually set any value. Similarly, the user can set an angle of the other axis, that is, the axis H through a GUI (8j) at the time of a second stage adjustment, that is, an adjustment of the axis V. For example, an optimum value obtained as a result of adjusting the axis H in a first stage adjustment is set to be used.

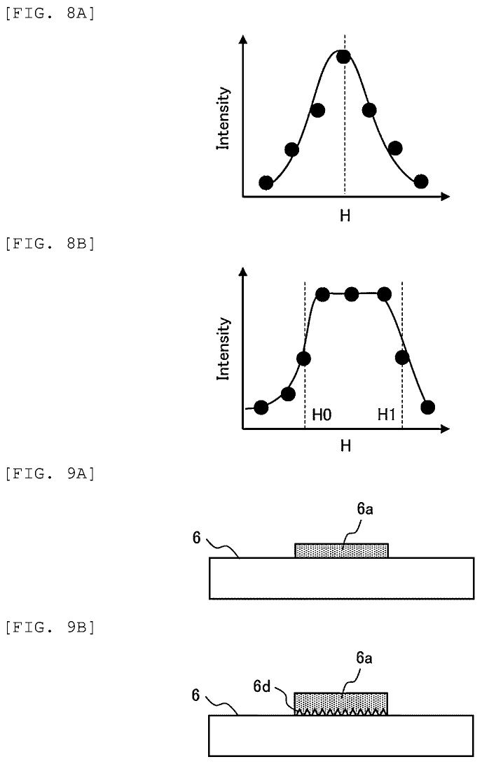

Next, when the user presses a start button, the control device starts light irradiation (step S5) and moves the angle of the axis V (step S6). Thereafter, while changing the value of the axis H, the angle of the axis H at which the magnitude of the electric signal of the detector selected by the user is maximum is extracted (step S7). For example, the secondary light signal is recorded while changing the angle of the axis H at regular intervals. In this case, since the secondary light amount increases when the light irradiation position passes through the reference structure, if the secondary light intensity is plotted as a function of the mirror angle, the function becomes a mountain shape as shown in FIG. 8A. In other words, in FIG. 8A, when the secondary light amount is measured in the direction of the axis H as shown in FIG. 2, the secondary light amount forms a curve having a prominent maximum value.

The result is displayed as a first scan result (graph 8k) in an adjustment result window as shown in FIG. 7B. The mirror angle having the maximum value is the adjusted mirror angle.

As a method of obtaining the mirror angle at which the secondary light intensity is maximum, a gradient method may be used. The gradient method is an algorithm also referred to as a gradient descent method, and is capable of obtaining maximum and minimum values with a small number of trials, thereby achieving an effect of quickly completing adjustment.

When the light irradiation diameter d is small with respect to the size of the reference structure 6a, the curve is not a mountain-shaped curve as shown in FIG. 8A, but a step function curve as shown in FIG. 8B (a curve having a range in which the secondary light amount becomes a substantially constant maximum value with respect to the change in the axis H). Furthermore, when power density in the light irradiation region (elliptical region 7a) has a spatially uniform distribution, that is, in a case of a flat top type spatial distribution, the step function type curve as shown in FIG. 8B is obtained. In this case, when the mirror angles at which the secondary light intensity decreases to ½ of the maximum value are set as H0 and H1, the optimum value of the mirror angle can be obtained as a peak center by (H0+H1)/2.

The algorithm for extracting the optimum mirror angle from the data shown in FIGS. 8A and 8B is not limited to the method using the maximum value or the method using the peak center as described above. The algorithm may be any algorithm that gives an optimum value from the mirror angle dependence of the signal amount output by the light detection system. For example, a method of fitting to a Gaussian function may be used, or a method based on a machine learning model may be used. A plurality of algorithms may be implemented in the control device. The control device may automatically determine and select which algorithm is to be used, or the user may perform the selection on the GUI.

Next, the control device adjusts the other adjustment axis, that is, the axis V in the same procedure (steps S8 to S9), and a second scan result (graph 8l) is displayed. In the window of FIG. 7B, conditions at the time of adjustment, for example, laser power and a used detector are also displayed in fields 8m.

The user can adjust the adjustment procedure of steps S1 to S9 in the order of the coarse adjustment reference structure and the fine adjustment reference structure. At the time of the adjustment, if the scan position of the mirror is largely deviated, since the light does not hit the reference structure, it is impossible to extract the mirror angle that maximizes the secondary light intensity, and an effect such that it is possible to coarsely adjust the irradiation position by first performing the adjustment using the coarse adjustment reference structure having a large dimension is exerted.

Furthermore, the fine adjustment reference structure having a dimension smaller than the light irradiation diameter is also provided on the single adjustment sample, so that an effect such that it is possible to switch between the coarse adjustment and the fine adjustment at high speed without replacing the sample, and to adjust the irradiation position with high accuracy is exerted.

After the fine adjustment is completed, set values of the movable axes H and V are stored in the storage unit 5e (FIG. 5). Preferably, all information used for setting is stored. The information includes, for example, a detector and ranges of H and V used for setting. The result may be automatically stored or may be manually stored after the user confirms the result. According to this procedure, the set value of the mirror angle for accurately matching the electron-beam irradiation position and the light irradiation position can be recorded and recalled later. When a deviation between the electron-beam irradiation position and the light irradiation position is small, the coarse adjustment procedure may be omitted, and the fine adjustment may be performed from the beginning.

The adjustment method according to the present embodiment uses an adjustment sample including a reference structure that generates secondary light in response to light irradiation, a control device that controls a light irradiation position, and a photodetector that detects the secondary light and generates an electric signal. The control device sequentially moves the light irradiation position in two directions so as to pass through the reference structure, and maximizes the generated secondary light amount, thereby exerting an effect of accurately adjusting the light irradiation position relative to the electron-beam irradiation position.

The adjustment method according to the present embodiment can also be applied to elimination of charging of the sample caused by irradiation of the charged particle beam. By accurately matching the light irradiation position and the irradiation position of the charged particle beam, the electric charges generated by the light irradiation can be efficiently injected into a charged region, and thus an effect of improving a charging elimination effect is exerted.

The reference structure used in the present embodiment is not limited to the periodic structure shown in FIG. 3, and can use various structures that emit the secondary light Ray2.

Hereinafter, Modifications 1 to 3 of the reference structure will be described.

### [Modification 1 of Reference Structure]

In Modification 1, an example in which a phosphor is used as the reference structure will be described.

For example, the phosphor may be any material that emits light having a different wavelength in response to the light, and may be, for example, a material such as YAG having a light emission center, or a semiconductor such as GaN. Alternatively, a material having a microstructure such as quantum dots, nanowires, or quantum wells may be used. A light emission wavelength may be any wavelength, for example, from ultraviolet to infrared wavelengths, but in a case where the ET detector is used as a secondary photodetector, when the same light emission wavelength as that of a scintillator is used, a wavelength region with high detection sensitivity can be used, which is more preferable. From another point of view, it is preferable to set a wavelength region in which the sensitivity of the light receiving element constituting the ET detector is high. When the phosphor is used as the reference structure, light having a wavelength different from that of the incident light can be used as the secondary light, and thus by using a color filter, a dichroic mirror, or the like, an effect such that it is possible to clearly detect the secondary light without being affected by incident light or reflection light is exerted.

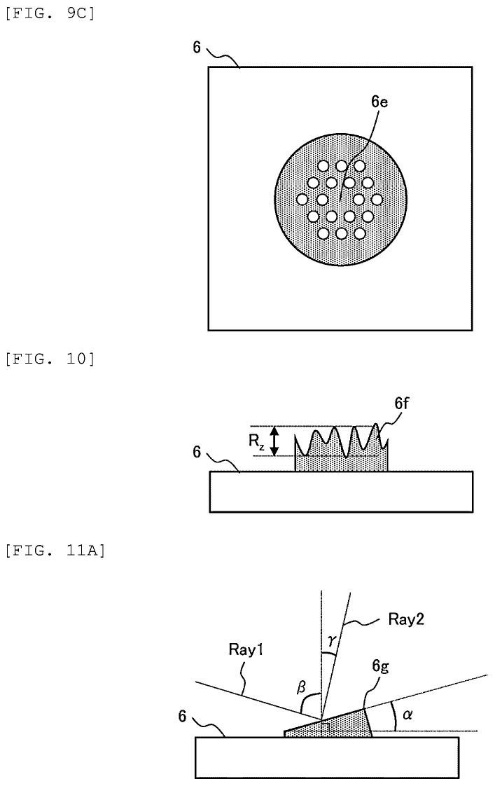

FIG. 9A is a cross-sectional view showing an example of the reference structure used in Modification 1.

In FIG. 9A, the adjustment sample 6 has the reference structure 6a of the phosphor.

The reference structure 6a may have a flat structure, but the secondary light signal amount can be increased by changing the structure.

Hereinafter, a method of increasing the secondary light will be described.

FIG. 9B is a cross-sectional view showing another example of the reference structure used in Modification 1.

In this drawing, a microstructure such as an uneven structure 6d of SiO₂ is formed on a surface of the substrate (made of Si) of the adjustment sample 6, and a surface of the uneven structure 6d is covered with a phosphor. According to such a configuration, light confined in the sample by total internal reflection can be extracted from the adjustment sample 6. Therefore, the secondary light amount can be increased. The confinement of light is caused by the total reflection occurring at an interface between the phosphor and air.

FIG. 9C is a top view showing another example of the reference structure used in Modification 1.

In this drawing, the phosphor is provided to form an optical resonator structure. Examples of the minute optical resonator used as the reference structure 6a shown in this drawing include an H1 type photonic crystal resonator 6e. However, the optical resonator structure is not limited thereto, and may be a fabry-perot resonator or a microdisk resonator. These optical resonators can increase the light emission amount and increase the secondary light amount.

As shown in FIGS. 9B and 9C, when a light structure is added to the phosphor, the secondary light amount that can be detected can be increased, and thus the effect of enabling the secondary light to be clearly detected is exerted.

### [Modification 2 of Reference Structure]

In Modification 2, a case where a scatterer is used as the reference structure will be described.

FIG. 10 is a cross-sectional view showing an example of the reference structure used in the present modification.

A scatterer 6f is a structure that emits light having the same wavelength toward an angle range in response to the incident light. The angle range of scattering is determined by surface roughness R_{z} of the scatterer 6f, and if a structure in which the photodetector is included in the angle range is used, the secondary light can be clearly detected, which is desirable. Since the secondary light emitted from the scatterer 6f emits the secondary light in various directions, when the scatterer 6f is used as a reference structure, an effect such that positions of detectors are adapted to various different types of charged particle beam devices is exerted.

In the present modification, a case where the surface of the scatterer 6f is roughened is described, but the present modification is not limited thereto. Examples include a scatterer in which titanium oxide is dispersed in a resin or the like, a scatterer using a polyester film having many flat voids therein, and a scatterer using a diffusing material such as barium sulfate.

### [Modification 3 of Reference Structure]

In the present modification, a modification in which a micromirror is used as the reference structure will be described.

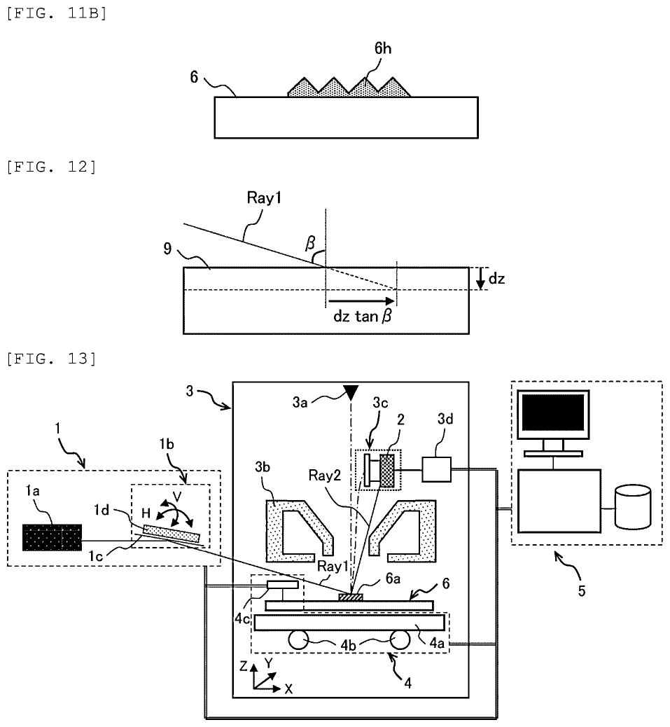

FIG. 11A is a cross-sectional view showing an example of the reference structure used in the present modification.

In this drawing, the adjustment sample 6 has a reference structure 6g of a micromirror.

A surface of the micromirror is a mirror surface, and light reflected by the micromirror is set as the secondary light. The mirror surface is inclined by an angle α with respect to a substrate surface of the adjustment sample 6, that is, the X-Y plane. When an incident angle of the incident light with respect to the X-Y plane is set as β, an angle of the light reflected by the micromirror is y=β−α. On the other hand, the light specularly reflected by the outer side of the reference structure 6g (the substrate surface of the adjustment sample 6) travels in a direction opposite to the incident light, that is, a direction of an angle −β, with the normal of the substrate surface of the adjustment sample 6 as an axis of symmetry. Therefore, the detector can detect only the reflection light on the micromirror. The micromirror may use a metal having a high reflectance in the wavelength region of the incident light, or may use a dielectric multilayer mirror.

When the micromirror is used as the reference structure 6g, all the light reflected by the micromirror is directed to the detector, and thus an effect of efficiently obtaining a clear secondary light signal is exerted. The surface of the micromirror may be a curved surface, and for example, in a case where the surface of the micromirror is formed as a parabolic surface, the light can be detected more efficiently by disposing the detector at a focal position of the parabolic surface.

FIG. 11B is a cross-sectional view showing another example of the reference structure used in the present modification.

In this drawing, the adjustment sample 6 has reference structure 6h in which a plurality of mirrors are arranged in an array.

In the reference structure 6h, the angle α can be increased without changing a thickness, and separation from specular reflection light traveling in the direction of the angle-β is facilitated. Therefore, it is possible to clearly detect a change in the secondary light amount.

Furthermore, the reference structure 6g (micromirror) may be a MEMS mirror, and the angle α may be controlled by an external control signal. According to such a movable mechanism, the angle of the secondary light to be generated is variable, and thus the detectors at different positions can be adapted to various different types of charged particle beam devices.

### Embodiment 2

The present embodiment differs from Embodiment 1 mainly in that the sample stage system of the charged particle beam device has a sample height sensor.

First, a problem will be described with reference to FIG. 12.

FIG. 12 is a schematic diagram showing an influence when a height of the sample changes in the present embodiment.

As shown in this drawing, when light is obliquely incident at an angle β to avoid a trajectory of the electron beam, if a height of a sample 9 is changed by dz, the light irradiation position is moved by a distance dz·tan β on a surface of the sample 9. Therefore, it is necessary to adjust the light irradiation position in accordance with the change in the height of the sample 9.

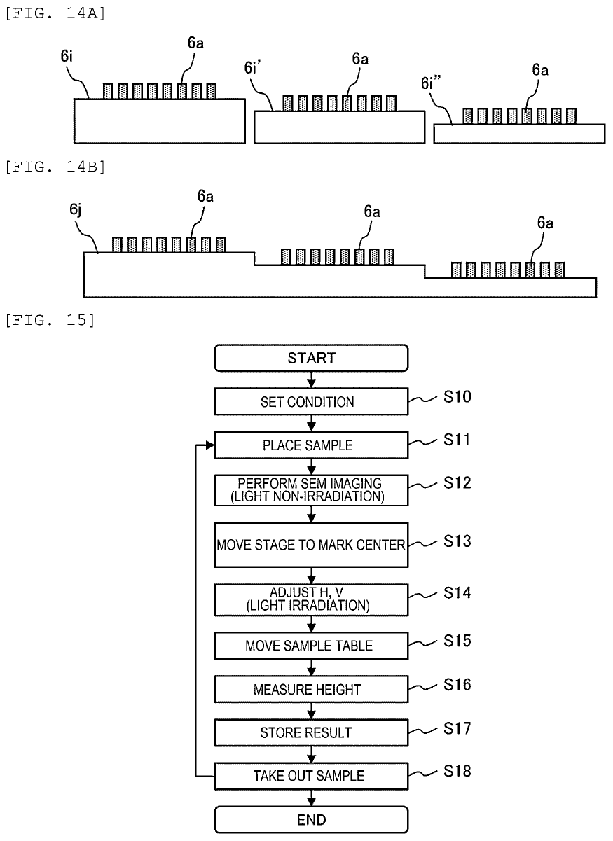

FIG. 13 is a schematic configuration diagram showing a charged particle beam device according to the present embodiment.

The charged particle beam device shown in this drawing is different from Embodiment 1 (FIG. 1) in that a height sensor 4c is provided.

The height sensor 4c measures the height of the sample. By calibrating to an optimum mirror angle according to an output value of the height sensor 4c, it is possible to adjust the light irradiation position with respect to the sample at any height.

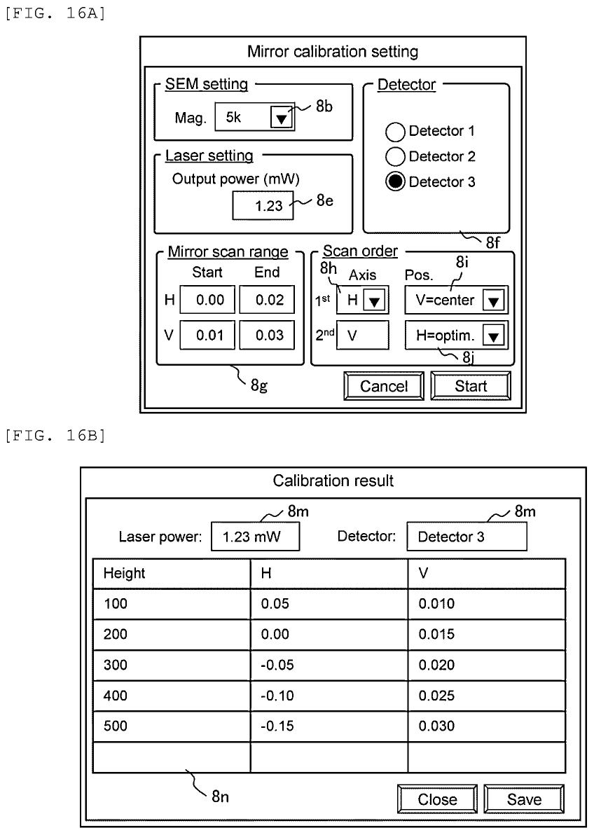

FIG. 14A is a cross-sectional view showing an example of the adjustment sample used in the present embodiment.

Adjustment samples 6i, 6i′, and 6i″ shown in this drawing are used for calibration. The adjustment samples 6i, 6i′, and 6i″ have substrates of different thicknesses and can be adjusted at different heights.

FIG. 14B is a cross-sectional view showing another example of the adjustment sample used in the present embodiment.

An adjustment sample 6j shown in this drawing has portions of different thicknesses, and the reference structure 6a is provided in each of the portions.

In the following description, FIG. 14A will be described as an example, but the same procedure can also be used when the sample as shown in FIG. 14B is used. In FIGS. 14A and 14B, only samples with three types of heights are shown, but it is needless to say that a sample with a larger number of types of heights may be used.

The height sensor is suitable because the height can be measured with high accuracy by using an optical lever type height sensor or a laser interferometer, and measurement method is not limited thereto, and a time of flight (ToF) type height sensor may be used, or the height may be measured mechanically. A configuration example of the height sensor is described in PTL 5 or the like.

Next, a procedure for calibrating the mirror angle will be described.

FIG. 15 is a flowchart showing a mirror angle calibration method.

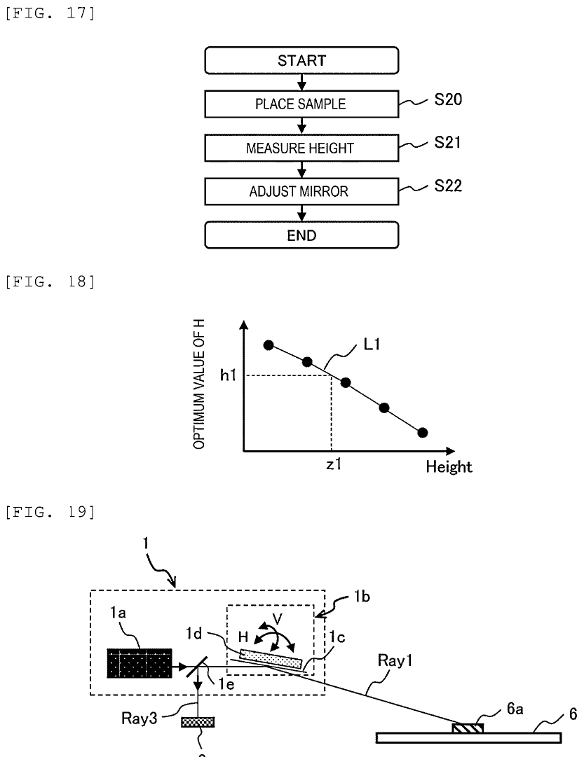

FIG. 16A is a diagram showing an example of a setting screen which is an operation GUI.

FIG. 16B is a diagram showing an example of a measurement value and an adjustment result of a height of a sample in the operation GUI.

First, the user inputs setting items (8b, 8e, 8f, 8g, 8 h, 8i, 8j) of light irradiation position adjustment (step S10). Since the setting items are the same as those in Embodiment 1, the description thereof is omitted.

Next, when the user presses a start button, the control device automatically uses the transfer arm or the like to place the adjustment sample on the sample table (step S11).

Next, the control device performs SEM imaging without emitting light (step S12). Then, the stage is moved such that the center mark appears at the center of the SEM image (step S13). The movement to the center can be automatically performed by an algorithm such as pattern matching as described in Embodiment 1. Alternatively, as described in Embodiment 1, the configuration may be such that the manual adjustment can be performed by an input of the user.

Next, the control device adjusts the mirror angles H and V as described in Embodiment 1 (step S14).

Next, the control device moves the sample stage to a flat portion having no reference structure (step S15). Then, the height of the sample is measured by the height sensor (step S16). By measuring the height at the flat portion, an effect such that it is possible to accurately measure the height without being affected by the reference structure is exerted.

Next, the measurement device stores the measurement value of the height of the sample and the adjustment result (H, V) in association with each other in the storage unit 5e (step S17). More preferably, the laser output at the time of adjustment and the conditions of the used detector are stored simultaneously.

Next, the control device uses the transfer arm or the like to take out the adjustment sample from the sample table (step S18).

Next, the control device returns to step S12 and performs the adjustment by using an adjustment sample with another height. When the adjustment is completed for all the adjustment samples, the adjustment step is ended.

When the above steps are completed, a table of optimum values of the mirror angles (H, V) corresponding to the values of the height sensor is constructed and displayed as a table 8n.

When the movable stage 4b also has a movable axis in a height direction (Z direction), a table in which the value of the height sensor and the value of the mirror angle are associated with each other may be created by changing the height of the movable stage 4b instead of using samples of different heights.

FIG. 17 is a flowchart showing an irradiation position adjustment method according to Embodiment 2.

A method of automatically adjusting the irradiation position according to the height of the sample will be described with reference to this drawing.

First, the user places the sample to be irradiated with the charged particle beam and light on the sample stage (step S20). Here, for example, when the charged particle beam device is the SEM, the sample means a sample to be observed. In this case, a height of the sample may be unknown.

Next, the control device measures the height of the sample by the height sensor (step S21).

Finally, the control device sets the values of the movable axes H and V by interpolation or extrapolation based on the table 8n (FIG. 16B) (step S22).

FIG. 18 is a graph of the table 8n in FIG. 16B. A horizontal axis represents the height of the sample, and a vertical axis represents the optimum value of the mirror angle.

Although FIG. 18 shows only the movable axis H as an example, the movable axis V can be adjusted in the same manner. Points shown in the graph of this drawing are values obtained in steps S10 to S17, and a curve is a line connecting these points. If the height of the sample is z1, an optimum mirror angle h1 is obtained as a value of a curve L1 with respect to the height z1 of the sample. In other words, the optimum mirror angle can be calculated by using the curve L1 obtained by interpolation. Alternatively, when the height of the sample is outside the range of the table 8n, the height of the sample can be obtained by the extrapolation based on data points within the range.

The adjustment method according to the present embodiment can automatically adjust the light irradiation position in conjunction with the height sensor. Accordingly, when light is obliquely incident on the sample, the electron-beam irradiation position and the light irradiation position can also be accurately matched regardless of the height of the sample.

### Embodiment 3

The present embodiment is different from Embodiment 1 mainly in that the photodetector is installed on a path of the incident light.

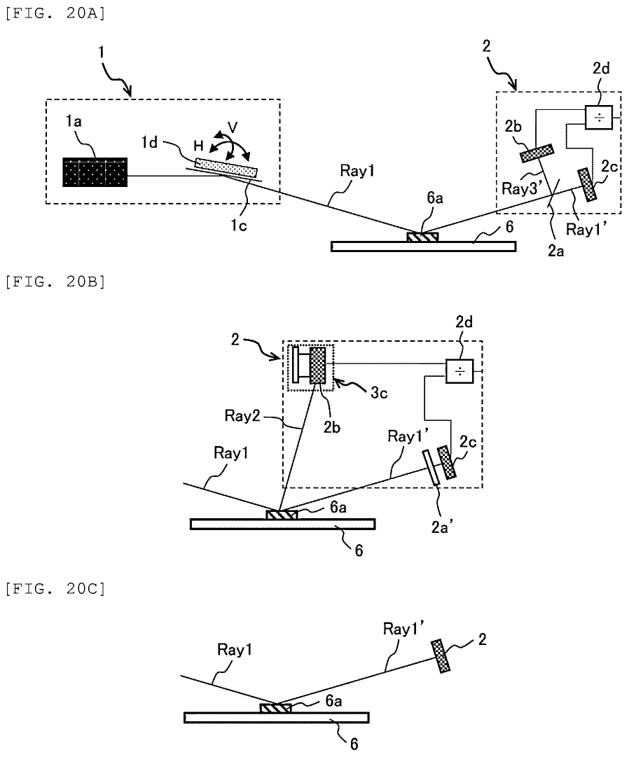

FIG. 19 is a configuration diagram showing only the light irradiation system and the light detection system. The other device configuration is the same as that of Embodiment 1, and thus the description thereof is omitted.

In this drawing, the light irradiation system 1 has a branching portion 1e on the path of the incident light. A beam splitter can be used as the branching portion 1e.

When the reference structure 6a of the adjustment sample 6 is irradiated with the light beam Ray1 (incident light), the secondary light Ray2 is generated. Since the secondary light Ray2 travels also in a direction (direction of 180 degrees) that is exactly opposite to the light beam Ray1, the secondary light Ray2 reaches the branching portion 1e. The secondary light Ray2 is split into a light beam passing through the branching portion 1e and traveling straight and a light beam Ray3 reflected by the branching portion 1e. The light detection system 2 detects the light beam Ray3 (secondary light).

In this way, the secondary light returning from the adjustment sample 6 is detected, so that the light irradiation system 1 and the light detection system 2 can be integrated, and thus an effect of making the device compact and facilitating installation in a charged particle beam device is exerted.

When a phosphor is used as the reference structure, a dichroic mirror can be used for the branching portion 1e. The dichroic mirror includes a short path type and a long path type. The short path type is characterized in that light having a wavelength shorter than a certain wavelength travels straight and light having a long wavelength is reflected. On the other hand, the long path type dichroic mirror is characterized in that light having a wavelength longer than a certain wavelength travels straight and light having a short wavelength is reflected.

In the configuration of the present embodiment, the fluorescence returning from the sample is reflected by the branching portion. Since the phosphor is a material that receives energy from the incident light and generates energy lower than the incident light, that is, light having a longer wavelength, a short path type that reflects light having a longer wavelength is suitable for the dichroic mirror. However, when positions of the light source and the light detection system are reversed, a long path type in which fluorescence with a long wavelength travels straight is suitable. By a configuration in which the dichroic mirror is used, the light path can be switched according to the wavelength, and more secondary light can be incident on the detector than in a case where the beam splitter is used, and an effect such that the secondary light can be detected more clearly is exerted.

A polarizing beam splitter may be used for the branching portion 1e. In this case, polarization of the secondary light needs to be different from polarization of the incident light, and for example, the polarizing beam splitter can be applied to a case where a scatterer or a phosphor is used as the reference structure. By the configuration in which the polarizing beam splitter is used, the light path can be switched in response to the polarization. When a non-polarizing beam splitter is used, a part of the secondary light signal travels straight through the beam splitter. Therefore, when the polarizing beam splitter is used, more secondary light can be reflected and incident on the detector. Therefore, an effect such that the secondary light can be detected more clearly is exerted.

### Embodiment 4

The present embodiment is different from Embodiment 1 mainly in that the photodetector is disposed on a path of the specular reflection light.

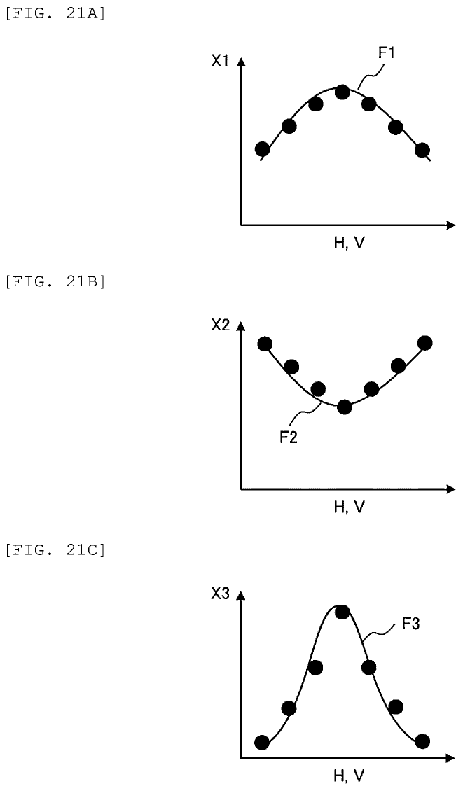

FIG. 20A is a configuration diagram showing only the light irradiation system and the light detection system. The other device configuration is the same as that of Embodiment 1, and thus the description thereof is omitted.

In this drawing, the light detection system 2 includes a branching portion 2a, two light receiving elements 2b and 2c, and a signal processing unit 2d.

The branching portion 2a splits the specular reflection light into reflection light Ray1′ and secondary light Ray3′. The secondary light Ray3′ is detected by the light receiving element 2b. The branched reflection light Ray1′ is detected by the light receiving element 2c. When a phosphor is used as the reference structure 6a, a dichroic mirror or a polarizing beam splitter can be used as described in Embodiment 3. When a scatterer is used as the reference structure 6a, a polarizing beam splitter can be used as described in Embodiment 3.

Next, changes in signal intensity X1 and X2 of the light receiving elements 2b and 2c in the adjustment of the light irradiation position will be described.

FIG. 21A is a graph showing the signal intensity X1 detected by the light receiving element 2b in FIG. 20A.

FIG. 21B is a graph showing the signal intensity X2 detected by the light receiving element 2c in FIG. 20A.

As described in Embodiment 1, when the light irradiation position is moved to pass through the reference structure, the signal intensity X1 of the secondary light becomes an upward convex curve F1 (FIG. 21A).

On the other hand, when the secondary light is generated, a part of the emitted light energy is converted into the secondary light, and thus intensity of the generated reflection light decreases (FIG. 21B). When the light irradiation position is moved to pass through the reference structure, intensity of the reflection light becomes a downward convex curve F2.

FIG. 21C is a graph showing an electric signal X3 calculated by the signal processing unit 2d in FIG. 20A.

The signal processing unit 2d receives the intensity X1 of the secondary light and the intensity X2 of the reflection light, calculates the new electric signal X3=X1/X2 by division, and outputs the electric signal X3 to the control system. A curve F3 thus obtained is steeper than the curves F1 and F2 (FIG. 21C). Therefore, when the adjustment described in Embodiment 1 is performed by using the curve F3 as an input signal, the signal changes significantly, and thus an effect such that it is possible to perform a robust adjustment of the irradiation position without being affected by noise or the like is exerted.

Arithmetic processing performed by the signal processing unit 2d is not limited to the division. For example, subtraction may be performed instead of the division, or an exponential function or a logarithmic function may be used.

In the case where a light irradiation system that emits light from an oblique direction is provided, it is desirable to provide a beam damper that terminates the light path in order to prevent the specular reflection light from exiting to the outside of the device and prevent internal members from being damaged due to turbulent reflection inside the device. In the configuration of the light detection system according to the present embodiment, the detector is provided on the path of the specular reflection light, and thus an effect of eliminating a need for a beam damper, simplifying the configuration, and enabling the secondary light to be detected more clearly is exerted.

### [Modification of Optical System]

FIG. 20B is a configuration diagram showing modification of the optical system.

Since the light irradiation system is the same as that of FIG. 20A, descriptions thereof will be omitted.

In the present modification, the electron-beam detection unit 3c as described in Embodiment 1 is used as the light receiving element 2b. In this case, the branching portion 2a of the light detection system 2 can be omitted, and the light receiving element 2c can be directly installed on the path of the reflection light. However, when a phosphor or a scatterer is used as the reference structure 6a, in addition to the reflection light, the fluorescence or scattered light may also enter the light receiving element 2c, and thus the light beam Ray1′ is detected through the optical element 2a′ that eliminates the secondary light. This is desirable because only the reflection light can be selectively detected. A color filter or a polarizer can be used for the optical element 2a′.

### [Modification of Reference Structure]

FIG. 20C is a configuration diagram showing a modification of the optical system.

The reference structure 6a shown in the drawing is implemented by a light absorber. The light beam Ray1 is absorbed and attenuated light is generated as reflection light Ray1′.

The reference structure 6a is made of a material or implemented by a structure which absorbs the light beam Ray1. As the material that absorbs the light beam Ray1, for example, amorphous carbon or graphite can be used, but the material is not limited thereto. Alternatively, a microstructure that does not reflect light may be used. As an example of the microstructure, a needle-like structure (black silicon) generated when Si is plasma-etched can be used.

In the present modification, the secondary light Ray2 is not generated. The irradiation position can be adjusted by using only the reflection light Ray1′ attenuated by the reference structure 6a. The light detection system 2 includes a single detector. The types of detectors that can be used are as described in Embodiment 1.

When the position of the mirror angle is changed by the method described in Embodiment 1, the amount of the reflection light Ray1′ decreases when the light irradiation position matches the reference structure 6a. This is similar to the downward convex curve F2 shown in FIG. 21B. Therefore, the control device can adjust the light irradiation position by obtaining the mirror angle that gives a minimum value of the curve F2. Since the light absorber can absorb light having a wavelength in a wide range, the use of the light absorber as the reference structure 6a exerts an effect such that the adjustment can also be performed when the light source emits light having a plurality of wavelengths.

### Embodiment 5

The present embodiment is different from Embodiment 1 mainly in that an adjustment sample in which the position of the center mark of the reference structure is shifted from a center coordinate of the original reference structure is used.

First, a problem will be described by taking a charged particle beam device, particularly an SEM as an example.

The SEM has an image shift function of moving an SEM observation range within a range of several tens of μm or more by using an electron-beam deflector without moving the sample stage. That is, a position away from the light irradiation position adjusted by using the adjustment sample may be observed. Therefore, it is necessary to set the light irradiation position to any coordinate within the X-Y plane in accordance with the movement of the electron-beam irradiation position.

In order to set the irradiation position at any coordinate in the X-Y plane, it is necessary to obtain conversion expressions that give the mirror angles (H, V) from the desired light irradiation position (x, y) in the X-Y plane. That is, it is necessary to obtain coordinate conversion expressions from an X-Y space to an H-V space.

More specifically, the coordinate conversion expressions are expressed by the following expressions (1) and (2).

$$H = AHX \cdot X + AHY \cdot Y + H 0 \qquad ( 1 )$$

$$V = AVX \cdot X + AVY \cdot Y + V 0 \qquad ( 2 )$$

Six coefficients (AHX, AHY, AVX, AVY, H0, V0) are determined.

In the present embodiment, the conversion expressions are expressed by linear expressions such as the above expressions (1) and (2), but the conversion expressions are not limited thereto. For example, in a case where the amount of the change in the irradiation position is curved with respect to the mirror angle, such as a case where light is condensed through a lens, the conversion expression may be created in consideration of a high-order term, for example, a second-order term or a third-order term. In the case of using the conversion expression in which the high-order term is taken into consideration, the curvature due to the lens can also be taken into consideration, and thus the effect of enabling accurate adjustment of the irradiation position is also exerted in cases where it is desired to adjust the irradiation range over such a wide range that the curvature occurs when a lens is included in the optical system.

FIG. 22 is a top view showing an example of an adjustment sample used to obtain the coordinate conversion expressions. The other device configuration is the same as that of Embodiment 1, and thus the description thereof is omitted.

As shown in this drawing, the adjustment sample 6 having three reference structures 6k1, 6k2, and 6k3 is used. This is because there are six coefficients to be determined. Each of the reference structures 6k1, 6k2, and 6k3 has the center mark 6c for detecting the center through the SEM observation. Structures, dimensions, and the like of the adjustment sample 6 and the reference structures 6k1, 6k2, and 6k3 are as described in Embodiment 1, and thus descriptions thereof will be omitted.

Regarding each of the reference structures 6kl, 6k2, and 6k3, the reference structure is disposed at a position where the position of the center mark 6c is shifted from the reference. For example, the reference structure 6kl is at a position shifted with respect to the position of the center mark 6c by Q1 (dx1, dy1). Similarly, the reference structures 6k2 and 6k3 are positioned at Q2 (dx2, dy2) and Q3 (dx3, dy3), respectively, with the center mark 6c as the origin. The coordinates of Q1 to Q3 may be freely selected, but since it is necessary to determine six coefficients, a vector Q102 and a vector Q103 must be linearly independent. In other words, when Q1 to Q3 are plotted in the X-Y plane, Q3 must not be on a straight line Q1-Q2.

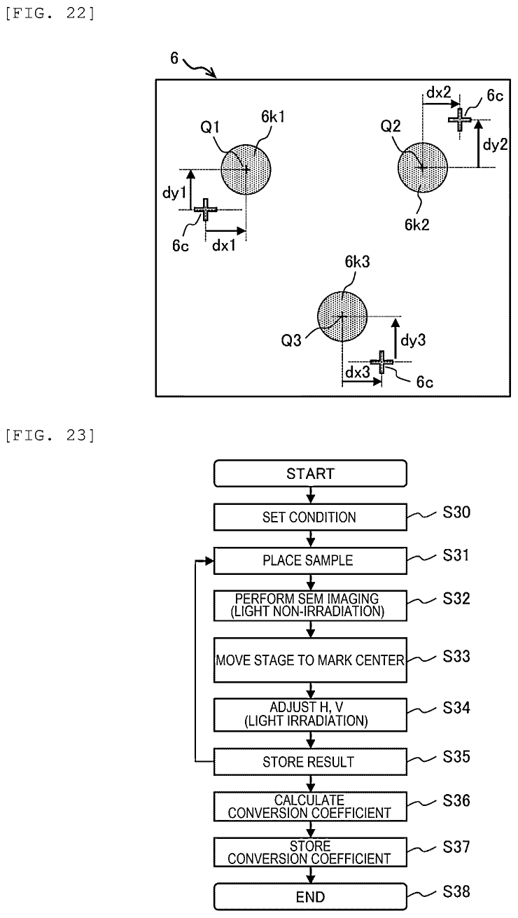

FIG. 23 is a flowchart showing an adjustment procedure for obtaining the coordinate conversion expression.

First, the user sets a condition of the light irradiation position adjustment (step S30). An example of a GUI of a setting screen may be the same as that of FIG. 16A, and a description thereof will be omitted.

Next, the control device transfers the adjustment sample to the sample table by using the transfer arm or the like (step S31).

Next, the control device performs the SEM imaging without emitting light (step S32). The sample stage is moved to the center mark position of the reference structure 6k1 (step S33). The control device acquires the SEM image, and moves the sample stage such that the center mark comes to the center of the SEM image by an algorithm such as pattern matching. In the case of the SEM having an image shift function, imaging is performed after the image shift is moved to the origin.

Next, the control device adjusts the irradiation position in the same manner as in Embodiment 1 (step S34).

Next, the control device records the adjustment result (H1, V1) in association with a deviation Q1 from the center mark (step S35).

Next, the control device moves the sample table to positions of the reference structures 6k2 and 6k3, and sequentially performs steps S32 to S35. Adjustment results (H2, V2) and (H3, V3) are recorded in association with Q2 and Q3, respectively.

Next, the control device calculates a conversion coefficient (step S36).

The control device substitutes the adjustment result into the above expressions (1) and (2) to obtain simultaneous equations. For example, the simultaneous equations obtained by substituting into the above expression (1) are expressed by the following expressions (3), (4), and (5).

$$H 1 = AHX \cdot X 1 + AHY \cdot Y 1 + H 0 \qquad ( 3 )$$

$$H 2 = AHX \cdot X 2 + AHY \cdot Y 2 + H 0 \qquad ( 4 )$$

$$H 3 = AHX \cdot X 3 + AHY \cdot Y 3 + H 0 \qquad ( 5 )$$

Since a degree of freedom is 3, the simultaneous equations (3), (4), and (5) can be solved, and the control device can obtain the coefficients AHX, AHY, and H0.

Similarly, the control device can obtain the coefficients AVX, AVY, and V0 by solving the simultaneous equation obtained by substituting into the above expression (2). Although an example in which three reference structures are used has been described in the present embodiment, an optimum coefficient may be numerically calculated by using four or more reference structures. By using more reference structures, an effect such that the coefficient can be determined with high accuracy is exerted.

Finally, device stores the conversion coefficients, that is, the coefficients AHX, AHY, H0, AVX, AVY, and V0 in the storage unit 5e (FIG. 5). More preferably, the height of the sample is also measured as in Embodiment 2, and the conversion coefficients are stored in association with the height of the sample.

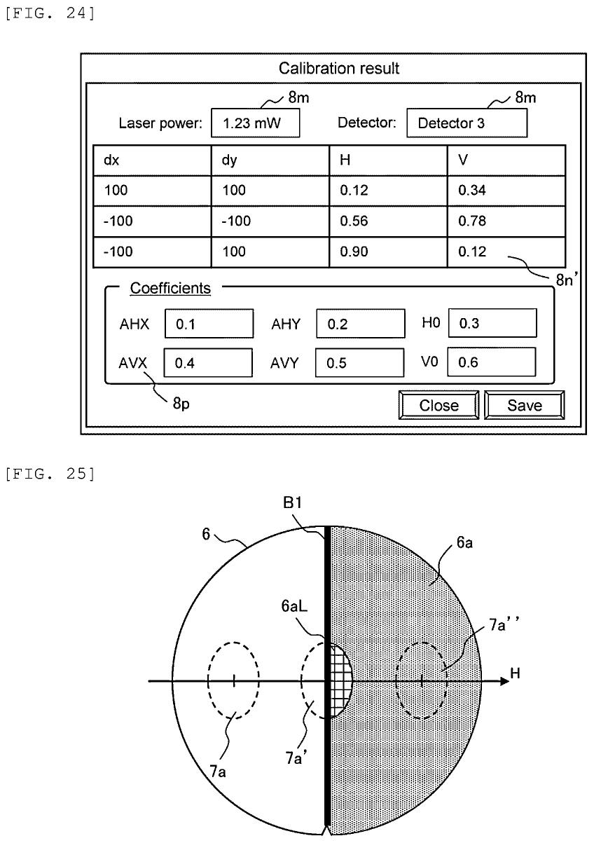

FIG. 24 is a diagram showing an example of a display GUI of the adjustment result.

Conditions of the adjustment are displayed in fields 8m. The condition of the adjustment is, for example, a laser output or a selected detector. The measurement results for the reference structures 6k1, 6k2, and 6k3 are displayed in a field 8n′. The conversion coefficients are displayed in a field 8p.

A method of adjusting the light irradiation position to any coordinate (x, y) on the sample by using the obtained coefficients will be described.

When (x, y) is substituted into the above expressions (1) and (2), mirror angles Hxy and Vxy to be set are calculated by the following expressions (6) and (7).

$$Hxy = AHX \cdot x + AHY \cdot y + H 0 \qquad ( 6 )$$

$$Vxy = AVX \cdot x + AVY \cdot y + V 0 \qquad ( 7 )$$

By adjusting the light irradiation position using the reference structure shifted by (x, y) with respect to the center marker as in the present embodiment, an effect such that a relative light irradiation position with respect to the irradiation position of the charged particle beam can be set freely.

### Embodiment 6

The present embodiment is mainly different from Embodiment 1 in that the adjustment is performed on a boundary line of the reference structure.

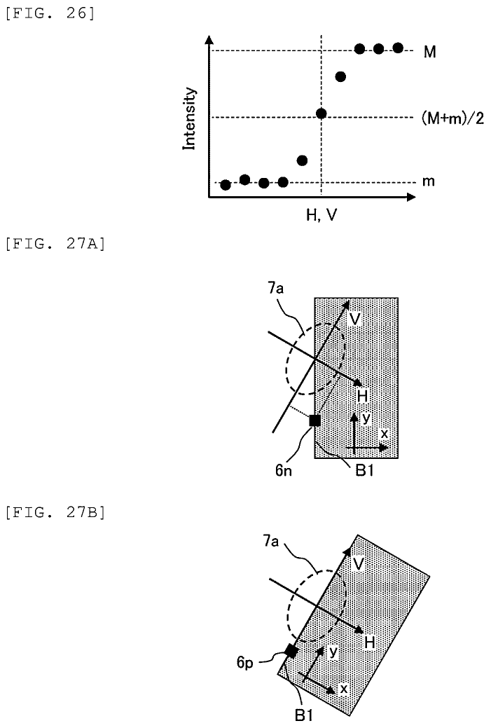

A principle will be described with reference to FIGS. 25 and 26.

FIG. 25 shows a structure example of the adjustment sample used in the present embodiment.

In this drawing, the semicircular reference structure 6a is provided on a right half of a wafer which is the adjustment sample 6. The reference structure 6a has a boundary line B1 passing through the center of the adjustment sample.

The sample stage is adjusted in advance such that the electron-beam irradiation position is on the boundary line B1. When the light irradiation position is adjusted to be on the boundary line B1 in this state, the electron-beam irradiation position and the light irradiation position can be adjusted to be on the same boundary line B1.

The boundary line refers to a line located at the boundary between an inside (a region where the reference structure is provided) and an outside (a region where the reference structure is not provided) of the reference structure. For example, when the reference structure is implemented by a periodic structure that emits diffracted light as described in Embodiment 1, the portion having the periodic structure is the inner side, and the portion having no periodic structure is the outer side. The boundary is defined as a boundary line. As described in Modification 6, when there are different types of reference structures, the boundary line may be a boundary line of these different types of reference structures. In either case, the electric signal amount generated in the detector may change before and after crossing the boundary line. For example, the amount, the wavelength, an angle distribution, and the like of the generated secondary light may be changed.

The control device moves a laser irradiation position in a direction intersecting with the boundary line B1. For example, FIG. 25 shows a case where when the adjustment axis H is moved, the control is performed to move the adjustment axis H from the outside (elliptical region 7a) to the inside (elliptical region 7a″) of the reference structure through the boundary line (elliptical region 7a′).

FIG. 26 is a diagram in which a change in the secondary light signal amount at this time is plotted as a function of the mirror angle. A horizontal axis represents a value of the axis H or the axis V, and a vertical axis represents the intensity of the secondary light.

When the irradiation position is outside the reference structure (elliptical region 7a), no secondary light is generated, but when the light irradiation region overlaps the boundary line, the secondary light signal starts to be detected. Since the secondary light amount is an amount of light emitted from a region 6aL where the reference structure and the light irradiation region are overlapped, the signal amount monotonically increases while the light irradiation region overlaps the boundary line. On the other hand, when the light irradiation region completely enters the reference structure, the secondary light amount becomes constant.

In this way, when the adjustment axis is moved to intersect with the boundary line, the signal amount is largely changed at a position of an intersection point, and thus an effect such that the coarse adjustment can be reliably performed even when the irradiation position is largely deviated is exerted.

Hereinafter, an example of an algorithm for adjusting the irradiation position based on such a change in the secondary light amount will be described. However, the algorithm is not limited to that described here. Any method may be used as long as the method is a data processing method for receiving a signal waveform and outputting the position, and Modification 4 will be described separately as an example of a different algorithm. A plurality of algorithms may be installed in the device. An optimal algorithm may be automatically selected by the control device, or may be input by the user.

A specific principle of the algorithm of the present embodiment will be described.

When the center of the light irradiation region is on the boundary line (elliptical region 7a′), a half of the light irradiation region exactly overlaps the reference structure, and thus the generated secondary light amount is also ½ of the maximum value. More specifically, when a minimum value in FIG. 26 is m and a maximum value is M, the secondary light amount is (m+M)/2. Hereinafter, (m+M)/2 is referred to as a target value It. It is unnecessary for the target value It to be exactly (m+M)/2. When the target value It is about (m+M)/2+0.2, the electron-beam irradiation region can be sufficiently irradiated with light. By setting a range of a tolerance value with respect to the target value in this way, it is possible to obtain an effect of being robust against noise of the secondary light signal. As the range of the tolerance value, the above-described standard may be used, or when adjustment with high accuracy is required, the user may designate a smaller value. In the case of using for the purpose of coarse adjustment, a larger tolerance value may be acceptable.

By utilizing this characteristic, the irradiation position can be adjusted by adjusting the mirror angle such that the secondary light amount becomes the target value It.

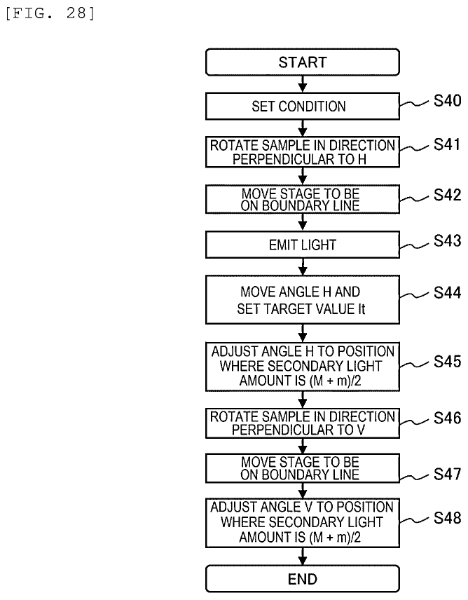

When the boundary line B1 intersects with the adjustment axis H at a right angle, the irradiation position can be adjusted more accurately. The reason will be described with reference to FIGS. 27A and 27B.

FIG. 27A is a diagram emphasizing the deviation of the irradiation position occurring when the movable axis H and the boundary line B1 are obliquely intersected.

An electron-beam irradiation range is 6n, and the light irradiation position of the adjusted movable axis H is 7a. The boundary line B1 is parallel to a y-axis.

In this case, only the position in a direction perpendicular to the boundary line B1 (y-axis), that is, an x coordinate can be adjusted by using the boundary line B1, and there is no sensitivity in a direction of the boundary line B1. Accordingly, the light irradiation position (elliptical region 7a) and the electron-beam irradiation position 6n are deviated in the direction of the boundary line B1 (y-axis). However, since the H-axis and the V-axis are inclined with respect to the x-axis and the y-axis, the adjustment is performed in a state where both the movable axis H and the movable axis V are deviated.

FIG. 27B is a diagram showing a case where the adjustment sample is rotated such that the boundary line B1 intersects with the movable axis H at a right angle.

In this case, as described with reference to FIG. 27A, the irradiation position is deviated in the direction of the boundary line B1, but can be accurately adjusted in the direction (H-axis direction) perpendicular to the boundary line B1. Although a specific procedure will be described later, the light irradiation position can be accurately matched with the electron-beam irradiation position by adjusting the V-axis in a state where the H-axis is fixed in the same manner.

As described above, an effect such that it is possible to accurately adjust the irradiation position by making the adjustment axis and the boundary line intersect at a right angle is exerted.

When the movable axis H and the boundary line B1 are oriented in directions that do not intersect at a right angle, the angle can be adjusted by rotating the adjustment sample as already described. Alternatively, when there are two or more movable axes of the mirror, the scan direction itself of the light irradiation position can be adjusted by interlocking the two or more movable axes.

Next, a procedure of adjusting the irradiation position in a two-dimensional surface by applying this principle will be described with reference to FIGS. 28,29, 30, and 31.

FIG. 28 is a flowchart of the adjustment.

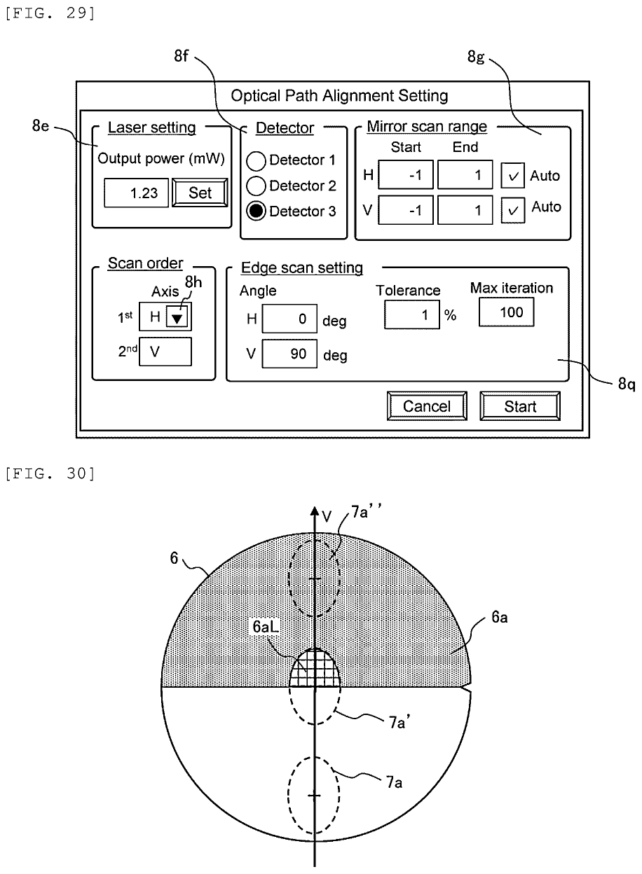

FIG. 29 shows an example of a GUI for inputting setting items according to the present embodiment.

FIG. 30 is a diagram showing a placing direction of the adjustment sample when the adjustment axis V is adjusted.

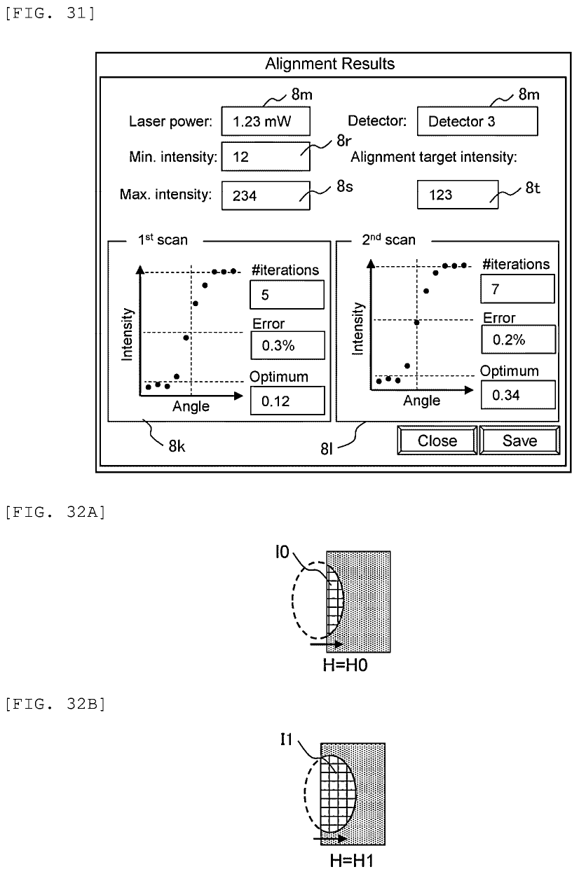

FIG. 31 shows an example of a GUI for displaying adjustment results of the present embodiment.

First, the user sets an adjustment condition (step S40). The setting items (8e, 8f, 8g, 8h) are the same as those in Embodiment 1, and therefore, descriptions thereof are omitted. Details of another setting item (8q) will be described in the following corresponding portions. In the present embodiment, an example in which the H-axis is selected as a first adjustment axis in the setting item 8h is described, and the V-axis can be adjusted first, and then the H-axis can be adjusted in the same manner.

When the user instructs to start the adjustment by a GUI operation or the like, the control device automatically transfers the adjustment sample to a sample chamber and causes the adjustment sample to rotate in a direction where the boundary line of the reference structure is perpendicular to the adjustment axis H (step S41). In this case, the angle of the adjustment axis H is designated by the user in the setting item 8q. Alternatively, when the mirror is fixed to the device and the angle is fixed, this setting item may be omitted and a fixed value may be used.

Subsequently, the control device moves the stage such that the boundary line B1 comes to the center of the SEM image (step S42). Alternatively, the user may manually move the stage while viewing the SEM image.

Next, the control device starts the light irradiation at the designated power (step S43), and records the maximum value M and the minimum value m of the secondary light amount while scanning the angle H. Alternatively, measurement may be performed at only two positions, that is, a lower limit and an upper limit of the scan range, and the larger value may be used as the maximum value M and the smaller value may be used as the minimum value m. In the present embodiment, an example in which the user designates a movement range of the angle H by the setting item 8q is shown, but the entire movable range of the mirror may be used without requesting the input of the user.

The control device calculates (m+M)/2 from the measurement value to set the target value It. The results are displayed in fields 8r, 8s, and 8t in FIG. 31 (step S44).

Next, the control device adjusts the angle H of the mirror such that the secondary light amount becomes the target value It (step S45). The adjustment can be performed by repeatedly adjusting the mirror angle until an error between the target value and the measurement value becomes equal to or less than a specified value. As a repetitive algorithm, a bisection method, a Newton method, or the like can be used.

The user can use the setting item 8q to set an error rate and a maximum number of repetitions to end the processing. Here, when IN represents the secondary light amount after the adjustment is performed N times, an error rate E is defined as E=|(IN−It)/It|.

When the error rate E falls below the specified value, the control device ends the adjustment. Alternatively, the adjustment is also ended when the number of repetitions N of the adjustment is equal to or greater than the value specified by the user. When the number of repetitions exceeds an upper limit value, the control device may omit the subsequent procedure to abnormally terminate the processing, or may continue the adjustment by using the mirror angle having the lowest error rate E. Alternatively, a dialog screen for confirming whether to continue the adjustment may be displayed to the user.

The number of repetitions of the final adjustment, the error rate, the adjusted mirror angle, and the angle dependence of the secondary light amount are displayed in the graph 8k. Alternatively, all or part of the result may be stored as a log file without being displayed on the screen.

Next, as shown in FIG. 30, the control device rotates the adjustment sample such that the boundary line is perpendicular to the V-axis, and moves the sample table such that the center of the field of view of the SEM is on the boundary line again (steps S46 to S47).

Finally, the control device adjusts the angle V such that the secondary light amount becomes the target value in the same procedure as the H-axis (step S48). Since the target value It has already been calculated in step S44, it is unnecessary to reset the target value before the adjustment of the V-axis. When the procedure of calculating the target value It again is performed after step S47, an effect such that accurate adjustment is possible even when the secondary light amount depends on an incident direction of light.

As described above, by rotating the adjustment sample to sequentially perform the adjustment on the boundary line in the two directions, it is possible to reliably perform the coarse adjustment even when the light irradiation position is largely deviated from the boundary line.

By combining the adjustments of the present embodiment and Embodiment 1, it is also possible to perform the adjustment more reliably and accurately. For example, when the light irradiation position is largely deviated from a diameter of a circle of the reference structure used in Embodiment 1, there may be a case where the coarse adjustment cannot be performed by the method of Embodiment 1. In this case, after the coarse adjustment is first performed by the method of the present embodiment, by returning to the method of Embodiment 1 and performing the adjustment, the coarse adjustment and the fine adjustment can be reliably performed.

### [Modification 4]

Modification 4 is a modification of the algorithm for performing the adjustment by maximizing a change rate in the secondary light amount.

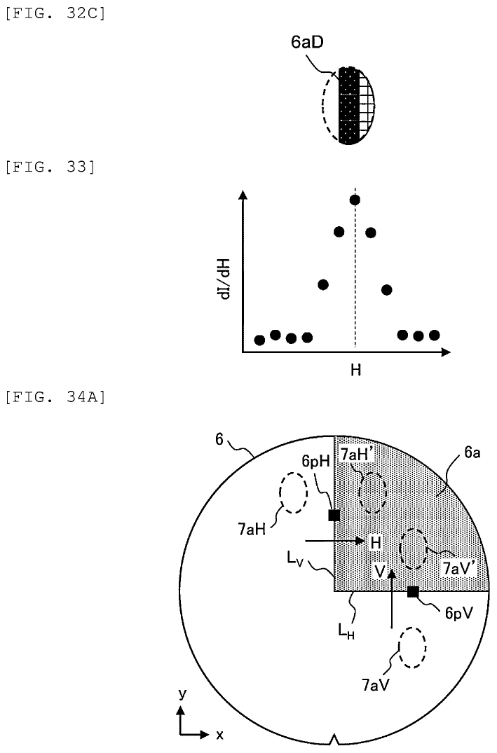

FIGS. 32A, 32B, and 32C are diagrams illustrating a change rate of the secondary light amount when the mirror angle H is changed from H0 to H1.

FIG. 33 is a graph showing an example of plotting the change rate of the secondary light amount as a function of the mirror angle H.

First, when the mirror angle is H0, the secondary light amount to be generated is determined by a region overlapping the reference structure, and the signal amount thereof is denoted by I0. Similarly, the secondary light amount to be generated when the mirror angle is moved to H1 is denoted by I1.

Here, since a signal increase amount I1−I0 when the mirror angle is moved from H0 to H1 is a difference between FIGS. 32A and 32B, the signal increase amount corresponds to the secondary light amount emitted from inside of a region 6aD in FIG. 32C. As described in Embodiment 1, since the light source such as a laser has a spatial distribution in which illuminance at the center is the highest, the signal increase amount I1−I0 is the largest when the region 6aD intersects with the center of the irradiation region.

When the change rate of the secondary light amount is defined as (I1−I0)/(H1−H0) in consideration of the amount of the change in the mirror angle, the change rate is a mountain-shaped function as shown in FIG. 33. A maximum value of the change rate is taken when the region 6aD passes through the center of the irradiation position. In other words, when the mirror is adjusted to a position where the change rate is maximum, the laser irradiation position can be matched with the boundary line of the reference structure.

By using the algorithm that maximizes the change rate in this way, it is possible to omit the procedure (step S44) of maximizing and minimizing the secondary light amount at the start of adjustment, and thus it is possible to exert an effect that the adjustment time can be shortened.

Since an algorithm for obtaining the maximum value can be used instead of an algorithm for repeatedly performing the adjustment to match the target value and the secondary light amount, the adjustment can be completed with a smaller number of repetitions by using the gradient method or the like.

### [Modification 5]

In Modification 5, a configuration example of a reference structure for performing the adjustment in a charged particle beam device having no rotation mechanism of the sample will be described.

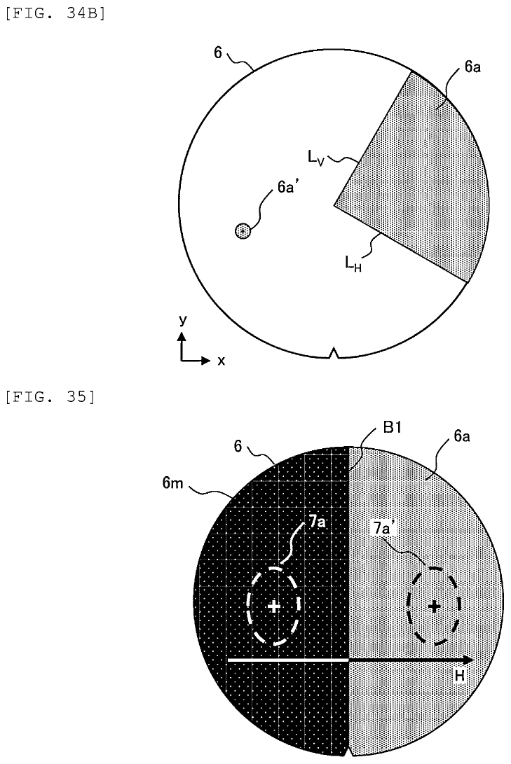

FIGS. 34A and 34B each show a structure example of the adjustment sample used in the present modification.

The adjustment sample 6 of the present modification has a structure in which ¼ of a wafer is implemented by the reference structure 6a, and has both a boundary line LH in a horizontal direction and a boundary line LV in a vertical direction.

An irradiation position adjustment procedure using the adjustment sample of the present modification will be described with reference to the flowchart of FIG. 28.

The user first performs the condition setting (step S40) and issues an adjustment start command to the device. In the present modification, an example in which the user sets to adjust the H-axis first will be described.

The control device moves the sample stage such that the electron-beam irradiation position is on the boundary line LV (step S42). The present modification is greatly different in that the step of rotating the sample (step S41) is unnecessary. However, since the boundary line LV has only a length to the center of the wafer, it is necessary to adjust the stage such that the electron-beam irradiation position becomes 6pH near the center of the boundary line LV in order to reliably perform the adjustment. After the movement of the stage, the control device adjusts the H-axis (steps S43 to S45). The movement range of the light irradiation position in this case is, for example, from a position 7aH to a position 7aH′.

Next, the V-axis is adjusted. Since the reference structure of the present embodiment additionally includes the boundary line LH in the lateral direction, the step S46 of rotating the sample is unnecessary. However, as in the case of adjusting the H-axis, since the boundary line LH has a length only to the center of the wafer, the sample stage is adjusted such that the electron-beam irradiation position becomes 6pV near the center of the boundary line (step S47). Finally, the V-axis is adjusted (step S48). The movement range of the light irradiation position in this case is, for example, from a position 7aV to a position 7aV′.

The structure that can be used in the present modification is not limited to such a structure, and for example, a square reference structure may be disposed at the center of the wafer and a boundary line thereof may be used.

In a case where the directions of the movable axes H and V are inclined with respect to the x and y axes due to the disposing of the adjustment mechanism, when the adjustment sample is produced at an angle at which the boundary lines LV and LH intersect with the movable axes H and V respectively at right angles as shown in FIG. 34B, the adjustment may be performed with high accuracy. In either case, the minimum number of non-parallel boundary lines may be two or more.

In this way, by using the reference structure having the boundary lines in a plurality of directions in the adjustment sample itself, an effect such that the procedure of rotating the adjustment sample can be omitted, and the adjustment time can be shortened is exerted. Since a mechanism for rotating the adjustment sample is not required, the device configuration can be simplified.

Furthermore, in a case of the adjustment sample as described in FIGS. 34A and 34B, since a lower left region is not used, the circular reference structure as described in Embodiment 1 can also be additionally disposed. By providing the reference structures having a plurality of structures in this way, it is possible to use a coarse adjustment reference structure that can be reliably adjusted at the time of coarse adjustment, and a fine adjustment reference structure that has a small number of times of movement of the stage at the time of fine adjustment and can be adjusted at a higher speed.

### [Modification 6]

In Modification 6, an adjustment example using a boundary line between two different reference structures will be described.

A structure of the sample will be described with reference to FIG. 35.

In this drawing, as in FIG. 25, the reference structure 6a is provided in the right half of the adjustment sample, and here, it is assumed that GaN emitting blue light is used as an example. In the present modification, in addition to this, the reference structure of GaAs emitting red light is on a left side. Although a combination of GaN and GaAs is used as an example in the present modification, another combination of fluorescence materials may be used. Alternatively, different types of reference structures may be combined, for example, the right side may have a periodic structure generating diffracted light, and the left side may be a fluorescence material. In either case, a combination of reference structures that generate different amounts of electric signals may be used.

A detection optical system when the present modification is used can use the optical system described in Embodiment 4. The fluorescence emitted from the sample is separated by the dichroic mirror. When the dichroic mirror is of a long path type, light emitted from the reference structure 6a is received by the light receiving element 2b, and light emitted from a reference structure 6m is received by the light receiving element 2c.

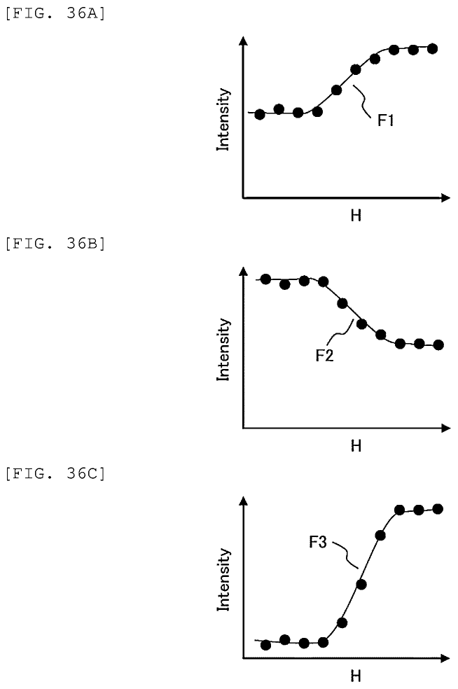

In FIG. 36A, a signal waveform F1 output from the light receiving element 2b is plotted, and in FIG. 36B, a signal waveform F2 output from the light receiving element 2c is plotted.

When the light irradiation position is in the elliptical region 7a, since GaAs emits light, the secondary light signal is detected by the light receiving element 2c but is not detected by the light receiving element 2b. On the other hand, when the irradiation position is in the elliptical region 7a′, since GaN emits light, the secondary light is detected only by the light receiving element 2b. Therefore, the waveform F1 and the waveform F2 show opposite position dependence.

In FIG. 36C, a signal output from the signal processing unit 2d as described in Embodiment 4 is plotted.

The signal processing unit 2d outputs, for example, a value obtained by dividing an output signal of the light receiving element 2b by an output signal of the light receiving element 2c. Since such a waveform F3 exhibits steeper characteristics than the waveforms F1 and F2 obtained by the single detector as described in Embodiment 4, an effect such that a more robust adjustment is possible is exerted.

Hereinafter, desired embodiments of the present disclosure will be collectively described.

The reference structure has a periodic structure, and when a wavelength of the first light is set as A and a refractive index of a medium on which the first light is incident is set as n, a period of the periodic structure is A/n or more and is smaller than an irradiation diameter of the first light.

The reference structure is made of a material that emits fluorescence in response to the first light.

The reference structure is made of a material or implemented by a structure which generates scattered light in response to the first light.

The reference structure is implemented by a mirror surface adjusted to an inclination at which reflection light is emitted in a direction of a photodetector.

The reference structure has a linear boundary line perpendicular to a movable axis of a movable mechanism.

The reference structure has a plurality of non-parallel boundary lines.

The irradiation position of the first light can be two-dimensionally adjusted.

The particle beam detector has a function of detecting light.

An adjustment sample includes a plurality of structures, and a distance between adjacent two of the plurality of structures is larger than an irradiation position movable range.

The adjustment sample has structures of different sizes, and the adjustment of the movable mechanism is performed in descending order of the sizes of the structures.

A charged particle beam device includes a height sensor configured to measure a height of a sample, in which the adjustment sample has portions of different heights, and the irradiation position of the first light on the sample at the heights is calibrated by adjusting the movable mechanism.

The periodic structure is two-dimensional.

The adjustment of the movable mechanism is performed such that intensity of second light detected by the photodetector is maximum.

The adjustment of the movable mechanism is performed such that the intensity of the second light detected by the photodetector is ½ of the maximum value.

The adjustment of the movable mechanism is performed such that a change rate of the intensity of the second light detected by the photodetector is maximum.

The second light includes reflection light and secondary light, and The adjustment of the movable mechanism is performed by using an electric signal derived from the reflection light and the secondary light.

The adjustment sample includes a marker for detecting a center by an image obtained by emitting a charged particle beam, the center of the reference structure of the adjustment sample is disposed at a position deviated from a center of the marker, and The adjustment of the movable mechanism is performed by using the reference structure.

The sample is irradiated with the first light from a direction different from the charged particle beam. Accordingly, the sample can be irradiated with light without interfering with an irradiation path of the charged particle beam, and components such as a lens and a prism for making the light parallel to the charged particle beam become unnecessary.

A control device moves the irradiation position of the first light so as to pass through a boundary line of the reference structure.

The reference structure has a linear boundary line, and the linear boundary line is perpendicular to a direction in which the irradiation position of the first light is moved by the movable mechanism.

The reference structure has a plurality of non-parallel boundary lines.

When a maximum value of a signal amount is set as M and a minimum value of the signal amount is set as m when the irradiation position of the first light passes through a boundary line of the reference structure, the control device adjusts the movable mechanism to a position where the signal amount is (M+m)/2.

The control device adjusts the movable mechanism to a position where a change rate of the signal amount when the irradiation position of the first light passes through a boundary line of the reference structure is maximum.

A control device moves the irradiation position of the first light so as to pass through a boundary line of the reference structure.

The present disclosure is not limited to the embodiment described above and includes various modifications. For example, the embodiments described above are described in detail in order to describe the present disclosure in an easy-to-understand manner, and are not necessarily limited to including all the described configurations. A part of a configuration of a certain embodiment can be replaced with a configuration of another embodiment or modifications, and the configuration of another embodiment or modifications can be added to the configuration of a certain embodiment. A part of a configuration of each example may be added to, deleted from, or replaced with another configuration.

### REFERENCE SIGNS LIST

1: light irradiation system
1a: light source
1b: light irradiation position adjustment unit
1c: optical element
1d: movable stage
2: light detection system
3: electron optical system
4: sample stage system
5: control system
6: adjustment sample
6a: reference structure
7a: elliptical region
7b: irradiation position movable range
9: sample

1. A light irradiation position adjustment method for adjusting an irradiation position of first light in a charged particle beam device, the charged particle beam device including:
a particle beam source configured to irradiate a sample with a charged particle beam;
a particle beam detector configured to detect a particle beam from the sample and generate a particle beam electric signal;
a light source configured to generate the first light with which the sample is irradiated;
a movable mechanism configured to move the irradiation position of the first light;
a photodetector configured to detect second light emitted from the sample due to the irradiation using the first light and generate a photoelectric signal;
a sample stage having a configuration allowing the sample to be placed and moved thereon; and
a control device, the method comprising:
the light source irradiating, with the first light, an adjustment sample placed on the sample stage and including a reference structure;
the photodetector detecting the second light, that is generated by the first light being modulated by the reference structure, and sending the photoelectric signal to the control device; and
the control device issuing a command to change the irradiation position of the first light so as to pass through the reference structure, and performing an adjustment, based on a change in the photoelectric signal, the movable mechanism such that an irradiation position of the charged particle beam and the irradiation position of the first light match.

2. The adjustment method according to claim 1, wherein
the reference structure has a periodic structure, and
when a wavelength of the first light is set as λ and a refractive index of a medium on which the first light is incident is set as n, a period of the periodic structure is λ/n or more and is smaller than an irradiation diameter of the first light.

3. The adjustment method according to claim 1, wherein
the reference structure is made of a material that emits fluorescence in response to the first light.

4. The adjustment method according to claim 1, wherein
the reference structure is made of a material or implemented by a structure which generates scattered light in response to the first light.

5. The adjustment method according to claim 1, wherein
the reference structure is implemented by a mirror surface adjusted to an inclination at which reflection light is emitted in a direction of the photodetector.

6. The adjustment method according to claim 1, wherein
the irradiation position of the first light is two-dimensionally adjustable.

7. The adjustment method according to claim 1, wherein
the particle beam detector has a function of detecting light.

8. The adjustment method according to claim 1, wherein
the adjustment sample includes a plurality of structures, and
a distance between adjacent two of the plurality of structures is larger than an irradiation position movable range.

9. The adjustment method according to claim 1, wherein
the adjustment sample has structures of different sizes, and
the adjustment of the movable mechanism is performed in descending order of the sizes of the structures.

10. The adjustment method according to claim 1, wherein
the charged particle beam device further includes a height sensor configured to measure a height of the sample,
the adjustment sample has portions of different heights, and
the irradiation position of the first light on the sample at the heights is calibrated by adjusting the movable mechanism.

11. The adjustment method according to claim 2, wherein
the periodic structure is two-dimensional.

12. The adjustment method according to claim 1, wherein
the adjustment of the movable mechanism is performed such that intensity of the second light detected by the photodetector is maximum.

13. The adjustment method according to claim 1, wherein
the second light includes reflection light and secondary light, and
the adjustment of the movable mechanism is performed by using an electric signal derived from the reflection light and the secondary light.

14. The adjustment method according to claim 1, wherein
the adjustment sample includes a marker for detecting a center by an image obtained by emitting the charged particle beam,
the center of the reference structure of the adjustment sample is disposed at a position deviated from a center of the marker, and
the adjustment of the movable mechanism is performed by using the reference structure.

15. The adjustment method according to claim 1, wherein
the first light is emitted to the sample from a direction different from the charged particle beam.

16. A charged particle beam device, comprising:
a particle beam source configured to irradiate a sample with a charged particle beam;
a particle beam detector configured to detect a particle beam from the sample and generate a particle beam electric signal;
a light source configured to generate first light with which the sample is irradiated;
a movable mechanism configured to move an irradiation position of the first light;
a photodetector configured to detect second light emitted from the sample due to the irradiation using the first light and generate a photoelectric signal;
a sample stage having a configuration allowing the sample to be placed and moved thereon; and
a control device, wherein
the light source irradiates, with the first light, an adjustment sample placed on the sample stage and including a reference structure,
the photodetector detects the second light, that is generated by the first light being modulated by the reference structure, and sends the photoelectric signal to the control device, and
the control device issues a command to change the irradiation position of the first light so as to pass through the reference structure, and performs an adjustment, based on a change in the photoelectric signal, the movable mechanism such that an irradiation position of the charged particle beam and the irradiation position of the first light match.

17. The charged particle beam device according to claim 16, wherein
the first light is configured to be emitted to the sample from a direction different from the charged particle beam.

18. The charged particle beam device according to claim 16, wherein
the irradiation position of the first light is two-dimensionally adjustable.

19. The charged particle beam device according to claim 16, wherein
the particle beam detector has a function of detecting light.

20. The charged particle beam device according to claim 16, further comprising:
a height sensor configured to measure a height of the sample, wherein
the adjustment sample has portions of different heights, and
the irradiation position of the first light on the sample at the heights is calibrated by adjusting the movable mechanism.

21. The charged particle beam device according to claim 16, wherein
the adjustment of the movable mechanism is performed such that intensity of the second light detected by the photodetector is maximum.

22. The charged particle beam device according to claim 16, wherein
the second light includes reflection light and secondary light, and
the adjustment of the movable mechanism is performed by using an electric signal derived from the reflection light and the secondary light.

23. The adjustment method according to claim 1, wherein
the control device moves the irradiation position of the first light so as to pass through a boundary line of the reference structure.

24. The adjustment method according to claim 23, wherein
the reference structure has a linear boundary line, and
the linear boundary line is perpendicular to a direction in which the irradiation position of the first light is moved by the movable mechanism.

25. The adjustment method according to claim 23, wherein
the reference structure has a plurality of non-parallel boundary lines.

26. The adjustment method according to claim 1, wherein
when a maximum value of a signal amount when the irradiation position of the first light passes through a boundary line of the reference structure is set as M and a minimum value of the signal amount is set as m, the control device adjusts the movable mechanism to a position where the signal amount is (M+m)/2.

27. The adjustment method according to claim 1, wherein
the control device adjusts the movable mechanism to a position where a change rate of a signal amount when the irradiation position of the first light passes through a boundary line of the reference structure is maximum.

28. The charged particle beam device according to claim 16, wherein
the control device moves the irradiation position of the first light so as to pass through a boundary line of the reference structure.

29. The charged particle beam device according to claim 16, wherein
when a maximum value of a signal amount when the irradiation position of the first light passes through a boundary line of the reference structure is set as M and a minimum value of the signal amount is set as m, the control device adjusts the movable mechanism to a position where the signal amount is (M+m)/2.

30. The charged particle beam device according to claim 16, wherein
the control device adjusts the movable mechanism to a position where a change rate of a signal amount when the irradiation position of the first light passes through a boundary line of the reference structure is maximum.
